(19) United States
(12) Patent Application Publication
(10) Pub. No.: US 2026/0337432 A1
(43) Pub. Date: Oct. 29, 2026

(54) QUANTUM DOT INK, QUANTUM DOT FILM AND DISPLAY PANEL

(71) Applicants: Beijing BOE Technology Development Co., Ltd., Beijing (CN); BOE Technology Group Co., Ltd., Beijing (CN)

(72) Inventor: Xiaoyuan ZHANG, Beijing (CN)

(73) Assignees: Beijing BOE Technology Development Co., Ltd., Beijing (CN); BOE Technology Group Co., Ltd., Beijing (CN)

(21) Appl. No.: 18/847,284

(22) PCT Filed: Nov. 30, 2023
(86) PCT No.: PCT/CN2023/135621

§ 371 Date: Sep. 16, 2024

(51) Int. Cl. C09D 11/50; B82Y 20/00; C09D 11/037; C09K 11/02; C09K 11/88; H10K 50/115

(52) U.S. Cl. CPC C09D 11/50; C09D 11/037; C09K 11/025; C09K 11/883; B82Y 20/00; H10K 50/115

(57) ABSTRACT

Embodiments of the present disclosure provide a quantum dot ink, a quantum dot film and a display panel, and relate to the field of display technologies. The quantum dot ink includes a quantum dot solution and a functional auxiliary agent miscible with the quantum dot solution. A volume percentage of the functional auxiliary agent in the quantum dot ink is in a range of 0.1% to 50%, inclusive. The functional auxiliary agent is configured to make a viscosity of the quantum dot ink greater than or equal to 2.0 mPa·s. The quantum dot ink is used to form a quantum dot film.

### CROSS-REFERENCE TO RELATED APPLICATION

This application is a national phase entry under 35 USC 371 of International Patent Application No. PCT/CN2023/135621, filed on Nov. 30, 2023, which is incorporated herein by reference in its entirety.

### TECHNICAL FIELD

The present disclosure relates to the field of display technologies, and in particular, to a quantum dot ink, a quantum dot film and a display panel.

### BACKGROUND

Quantum Dots (QDs) are semiconductor nanocrystals which have unique photoelectric properties, and may emit pure and high-quality monochromatic light depending on the molecular sizes of the quantum dots when stimulated by light or electricity. Due to nanoparticle properties of the quantum dots, the quantum dot material has solution processibility, and the quantum dot film may be formed by coating or spraying quantum dot ink.

### SUMMARY

In an aspect, a quantum dot ink is provided. The quantum dot ink includes a quantum dot solution and a functional auxiliary agent miscible with the quantum dot solution. A volume percentage of the functional auxiliary agent in the quantum dot ink is in a range of 0.1% to 50%, inclusive. The functional auxiliary agent is configured to make a viscosity of the quantum dot ink greater than or equal to 2.0 mPa·s.

In some embodiments, the quantum dot solution includes quantum dot materials and a solvent. A quantum dot material includes a quantum dot body. The functional auxiliary agent includes a first molecular skeleton and at least one first coordinating group grafted onto the first molecular skeleton. One or more first coordinating groups of the functional auxiliary agent are coordinated with the quantum dot body.

In some embodiments, the quantum dot material further includes a ligand material coordinated with the quantum dot body. At least part of quantum dot bodies are each coordinated with both a ligand material and a functional auxiliary agent.

In some embodiments, in a case where the functional auxiliary agent includes a first coordinating group, the first coordinating group is a first selected coordinating group; and in a case where the functional auxiliary agent includes at least two first coordinating groups, in the at least two first coordinating groups, a first coordinating group having strongest coordination ability with the quantum dot body is the first selected coordinating group. The ligand material includes a second coordinating group, and the ligand material is coordinated with the quantum dot body through the second coordinating group. The first selected coordinating group is same as the second coordinating group. Alternatively, the first selected coordinating group is different from the second coordinating group, and a coordination ability of the first selected coordinating group with the quantum dot body is stronger than a coordination ability of the second coordinating group with the quantum dot body.

In some embodiments, the second coordinating group is a sulfhydryl group, and the first selected coordinating group is a sulfhydryl group; alternatively, the second coordinating group is a carboxyl group, and the first selected coordinating group is any of a carboxyl group and a sulfhydryl group; alternatively, the second coordinating group is a sulfonic acid group, and the first selected coordinating group is any of a sulfhydryl group, a carboxyl group and a sulfonic acid group; alternatively, the second coordinating group is a phosphate group, and the first selected coordinating group is any of a sulfhydryl group, a carboxyl group, a sulfonic acid group and a phosphate group; alternatively, the second coordinating group is an amine group, and the first selected coordinating group is any of a sulfhydryl group, a carboxyl group, a sulfonic acid group, a phosphate group and an amine group; alternatively, the second coordinating group is a phospholipid group, and the first selected coordinating group is any of a sulfhydryl group, a carboxyl group, a sulfonic acid group, a phosphate group, an amine group and a phospholipid group.

In some embodiments, in a case where the functional auxiliary agent includes a first coordinating group, the first coordinating group is a first selected coordinating group; and in a case where the functional auxiliary agent includes at least two first coordinating groups, in the at least two first coordinating groups, a first coordinating group having strongest coordination ability with the quantum dot body is the first selected coordinating group. The ligand material includes a second coordinating group, and the ligand material is coordinated with the quantum dot body through the second coordinating group. A coordination ability of the second coordinating group with the quantum dot body is stronger than a coordination ability of the first selected coordinating group with the quantum dot body. A volume percentage of the functional auxiliary agent in the quantum dot ink is greater than or equal to 5%.

In some embodiments, in a case where the functional auxiliary agent includes a first coordinating group, the first coordinating group is a first selected coordinating group; and in a case where the functional auxiliary agent includes at least two first coordinating groups, in the at least two first coordinating groups, a first coordinating group having strongest coordination ability with the quantum dot body is the first selected coordinating group. The ligand material includes a second molecular skeleton and a second coordinating group grafted onto the second molecular skeleton, and the ligand material is coordinated with the quantum dot body through the second coordinating group. A coordination ability of the second coordinating group with the quantum dot body is stronger than a coordination ability of the first selected coordinating group with the quantum dot body. A steric hindrance of the second molecular skeleton is greater than a steric hindrance of the first molecular skeleton.

In some embodiments, the first selected coordinating group is a carboxyl group, and the second coordinating group is a sulfhydryl group; alternatively, the first selected coordinating group is a sulfonic acid group, and the second coordinating group is any of a sulfhydryl group and a carboxyl group; alternatively, the first selected coordinating group is a phosphate group, and the second coordinating group is any of a sulfhydryl group, a carboxyl group and a sulfonic acid group; alternatively, the first selected coordinating group is an amine group, and the second coordinating group is any of a sulfhydryl group, a carboxyl group, a sulfonic acid group and a phosphate group; alternatively, the first selected coordinating group is a phospholipid group, and the second coordinating group is any of a sulfhydryl group, a carboxyl group, a sulfonic acid group, a phosphate group and an amine group.

In some embodiments, the number of carbon atoms in the first molecular skeleton is greater than or equal to 4 and less than or equal to 8.

In some embodiments, the quantum dot solution includes quantum dot materials and a solvent; and a boiling point of the functional auxiliary agent is greater than a boiling point of the solvent.

In some embodiments, a viscosity of the functional auxiliary agent is greater than or equal to 5.0 mPa·s.

In some embodiments, the first coordinating group includes a sulfhydryl group and/or a carboxyl group; and the volume percentage of the functional auxiliary agent in the quantum dot ink is in the range of 0.1% to 50%, inclusive.

In some embodiments, the functional auxiliary agent is selected from any one or a combination of 3-mercaptobutyric acid, 5-mercaptopentanoic acid, heptyl mercaptan, octyl mercaptan, isooctyl mercaptan, 2-sulfhydryl-2,4-pentanediol, 2-methyl-2,4-pentanedithiol, 1,5-pentanedithiol, polythiol oligomer and 5-aminovaleric acid.

In some embodiments, the first coordinating group includes an amino group and/or an amine group; and the volume percentage of the functional auxiliary agent in the quantum dot ink is in a range of 0.1% to 30%, inclusive.

In some embodiments, the functional auxiliary agent is selected from any one or a combination of ethanolamine, dimethylethanolamine, N,N-dimethylethylenediamine, 1,2-diaminopropane, 2-methylbutylenediamine, 2-methylpentanediamine and 5-aminovaleric acid.

In some embodiments, the first coordinating group includes a phosphate group and/or a phospholipid group; and the volume percentage of the functional auxiliary agent in the quantum dot ink is in a range of 0.1% to 30%, inclusive.

In some embodiments, the functional auxiliary agent is selected from any one or a combination of fatty alcohol ether phosphate and fatty alcohol polyoxyethylene ether phosphate.

In some embodiments, the first coordinating group includes a sulfonic acid group; and the volume percentage of the functional auxiliary agent in the quantum dot ink is in a range of 0.1% to 30%, inclusive.

In some embodiments, the functional auxiliary agent is selected from any one or a combination of octane sulfonic acid, decylsulfonic acid, dodecyl sulfonic acid, tetradecyl sulfonic acid, 1-hexadecanesulfonic acid, octadecyl sulfonic acid, 4-decylbenzenesulfonic acid, dodecylbenzenesulfonic acid, tetradecylbenzenesulfonic acid, hexadecylbenzenesulfonic acid and octadecylbenzenesulfonic acid.

In some embodiments, in the quantum dot solution, a concentration of the quantum dot materials in the quantum dot solution is greater than or equal to 5.0 mg/mL and less than or equal to 50 mg/mL.

In another aspect, a quantum dot film is provided. The quantum dot film is made of the quantum dot ink as described in any of the above embodiments.

In some embodiments, a material of the quantum dot film includes the functional auxiliary agent.

In yet another aspect, a display panel is provided. The display panel includes a plurality of quantum dot films each as described in any of the above embodiments and a barrier layer. The barrier layer includes a plurality of openings, and the plurality of quantum dot films are located in the plurality of openings.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a light-emitting substrate, in accordance with some embodiments;

FIG. 2 is a structural diagram of a display panel, in accordance with some embodiments;

FIG. 3 is a morphology diagram of a quantum dot film, in accordance with some embodiments;

FIG. 4 is a morphology diagram of another quantum dot film, in accordance with some embodiments;

FIG. 5 is a morphology diagram of another quantum dot film, in accordance with some embodiments;

FIG. 6 is a morphology diagram of another quantum dot film, in accordance with some embodiments;

FIG. 7 is a morphology diagram of another quantum dot film, in accordance with some embodiments;

FIG. 8 is a morphology diagram of another quantum dot film, in accordance with some embodiments;

FIG. 9 is a morphology diagram of another quantum dot film, in accordance with some embodiments;

FIG. 10 is a morphology diagram of another quantum dot film, in accordance with some embodiments;

FIG. 11 is a curve graph showing a change in current versus voltage, in accordance with some embodiments;

FIG. 12 is a curve graph showing a change in brightness versus current density, in accordance with some embodiments; and

FIG. 13 is a curve graph showing a change in current efficiency versus current density, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of or” the plurality of means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

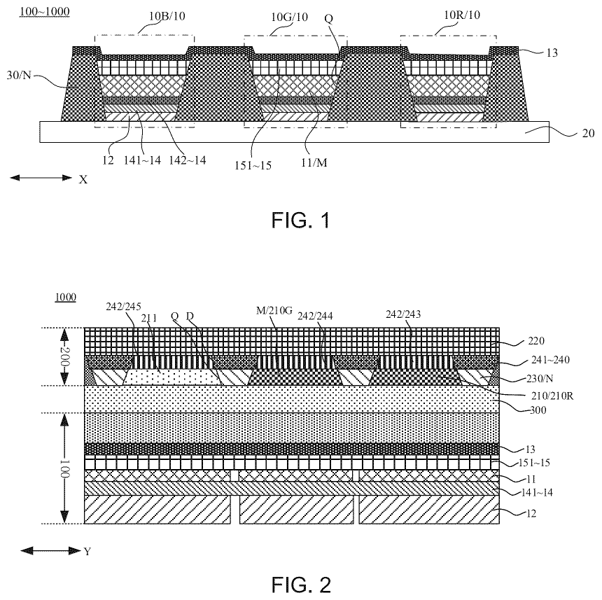

It will be noted that, a mark such as “11~1” appearing in the drawings of the present disclosure indicates that a component 11 belongs to a component 1. For example, a mark “241~240” in FIG. 2 indicates that a light absorption pattern 241 belongs to a light barrier layer 240, and other similar marks appearing in the drawings also follow the above description. Moreover, a mark such as ½” appearing in the drawings of the present disclosure indicates that a structure 1 and a structure 2 may both refer to this structure. For example, a mark “10G/10” in FIG. 1 indicates that a green light-emitting device 10G and a light-emitting device 10 may both refer to this structure, and other similar marks appearing in the drawings also follow the above description.

Nanometer materials usually have special mechanical, optical, magnetic, electrical, catalytic and other properties, and therefore have high use value. Quantum dots (QDs), also known as nanocrystals, have been widely studied in recent years due to their special photophysical properties, and have a variety of applications in photoelectric devices, sensors, energy storage, and the like.

In recent years, quantum dot materials have been used more and more widely in photoelectric devices, and many scientific researchers have done a lot of research on device efficiency and lifespan. At present, the efficiencies of quantum dot devices may reach a very high level. In some examples, efficiencies a red light-emitting device, a green light-emitting device and a blue light-emitting device may reach external quantum efficiencies (EQE) of 25%, 20% and 20%, respectively. The lifespans of some light-emitting devices (e.g., red light-emitting devices and green light-emitting devices) have reached a relatively high level, which reaches a level that can be mass-produced and promoted.

The manufacturing process of the quantum dot film includes a slit coating process, an inkjet printing process, a photolithography process, a transfer printing process, and the like. In the slit coating process and the inkjet printing process, the quantum dot film is formed by coating or spraying quantum dot ink.

The slit coating process is different from a spin coating process used in the laboratory and is more suitable for large-area film formation on the production line. A working principle of the slit coating process is, for example, that a surface of a substrate is coated by squeezing and spraying a coating solution along a slit lip of a coating die under a certain pressure and at a certain flow rate. Compared with other coating processes, the slit coating process has many advantages such as fast coating speed, high precision, uniform wet film thickness, closed system, high slurry utilization rate, and simultaneous multi-layer coating.

Based on the above principles, the slit coating process has certain requirements for performance of the solution used. For example, the solution viscosity is required to reach or exceed a set viscosity value, and the set viscosity value may be in a range of 2.0 mPa·s to 4.0 mPa·s; and/or the solid content of the quantum dot material in the solution is required to reach a set solid content value, and the set solid content value may be in a range of 20% to 30%.

In some implementations, when a quantum dot film is formed by slit coating, a thickness of a single-layer quantum dot film is required to be in a range of 20 nm to 50 nm, inclusive. Within this thickness range, the viscosity of the quantum dot ink is usually less than the above set viscosity value, for example, less than 2.0 mPa·s. In this case, limited by the viscosity of the quantum dot ink itself, the process controllability during large-area coating and drying is poor, making large-area uniform coating and drying a major challenge. Therefore, how to improve the uniformity of large-area film formation and drying is the key to the early realization of industrial application of quantum dot luminescence technology.

In some other implementations, in the slit coating process and the inkjet printing process, due to the low viscosity and the high fluidity of the quantum dot ink, large-area quantum dot ink is prone to liquid migration during drying, resulting in a coffee ring-like mark (commonly known as a coffee ring effect) of the quantum dot film obtained by drying, thereby affecting the film-forming quality.

In light of this, some embodiments of the present disclosure provide a quantum dot ink. The quantum dot ink includes a quantum dot solution and a functional auxiliary agent miscible with the quantum dot solution. A volume percentage of the functional auxiliary agent in the quantum dot ink is in a range of 0.1% to 50%, inclusive. The functional auxiliary agent is configured to make the viscosity of the quantum dot ink greater than or equal to 2.0 mPa·s.

The quantum dot solution and the functional auxiliary agent are miscible, which means that the quantum dot solution and the functional auxiliary agent can form a homogeneous system with relatively uniform physical and chemical properties after being mixed. Here, there is no limitation on the state (e.g., liquid or solid) of the functional auxiliary agent.

In some examples, the quantum dot solution includes a quantum dot material and a solvent. In this case, as a possible implementation, the solvent can be miscible with the functional auxiliary agent, so as to achieve miscible dissolution of the quantum dot solution and the functional auxiliary agent. Furthermore, the solvent may be a single solvent or a mixed solvent, which is not limited here. In this case, there is no limitation on the type of the single solvent and the type and amount of the mixed solvent, as long as the solvent and the quantum dot material can form the quantum dot solution and the quantum dot solution may be miscible with functional auxiliary agent.

For example, the volume percentage of the functional auxiliary agent in the quantum dot ink is 0.1%, 0.5%, 1.0%, 5.0%, 10.0%, 15.0%, 20.0%, 24.0%, 30.0%, 35.0%, 40.0%, 46.0% or 50%.

For example, due to action of the functional auxiliary agent, the viscosity of the quantum dot ink is 2.0 mPa·s, 2.3 mPa·s, 2.6 mPa·s, 3.0 mPa·s, 3.5 mPa·s, 4.0 mPa·s, 5.0 mPa·s or 6.0 mPa·s. It will be noted that the viscosity values listed above are examples of the viscosity of the quantum dot ink, and are not limitation on the viscosity of the quantum dot ink.

It can be understood that in a case where the viscosity of the quantum dot ink is greater than or equal to 2.0 mPa·s, the viscosity of the quantum dot ink is relatively high. In this way, the process controllability during film forming and drying may be improved, and thus the uniformity of large-area coating and drying during manufacturing the quantum dot film may be improved. Moreover, the fluidity of the quantum dot solution may be reduced, the volatility of the quantum dot ink may be reduced, the migration of the quantum dot solution may be reduced, and the coffee ring effect appearing during drying may be alleviated. Therefore, the film-forming quality of the formed quantum dot film may be improved.

Here, there is no limitation on the manner and the principle of adjusting the viscosity of the quantum dot ink by the functional auxiliary agent, as long as the viscosity of the quantum dot ink may be greater than or equal to 2.0 mPa·s.

In some examples, the functional auxiliary agent itself has a relatively high viscosity. In this case, the functional auxiliary agent and the quantum dot solution, after being miscible with each other, may form the quantum dot ink having a viscosity greater than or equal to 2.0 mPa·s. In some other examples, the functional auxiliary agent and the quantum dot solution may undergo chemical reaction to produce a material with a relatively high viscosity, so as to increase the viscosity of the quantum dot ink.

In some embodiments, the viscosity of the functional auxiliary agent is greater than or equal to 5.0 mPa·s.

For example, the viscosity of the functional auxiliary agent is 5.0 mPa·s, 10.0 mPa·s, 20.5 mPa·s, 50.0 mPa·s, 100.0 mPa·s, 250.0 mPa·s, 400.0 mPa·s, 500.0 mPa·s, 800.0 mPa·s, 1000.0 mPa·s or 5000.0 mPa·s. It will be noted that the viscosity values listed above are examples of the viscosity of the functional auxiliary agent, and are not limitation on the viscosity of the functional auxiliary agent.

It can be understood that in a case where the viscosity of the functional auxiliary agent is greater than or equal to 5.0 mPa·s, the viscosity of the functional auxiliary agent is relatively high. In this way, the functional auxiliary agent and the quantum dot solution, after being miscible with each other, may form the quantum dot ink with a viscosity greater than or equal to 2.0 mPa·s. In this way, the uniformity of large-area coating and drying during manufacturing the quantum dot film may be improved, and the coffee ring effect appearing during drying may be alleviated.

In some embodiments, the quantum dot solution includes quantum dot materials and a solvent. The quantum dot material includes a quantum dot body. The functional auxiliary agent includes a first molecular skeleton and at least one first coordinating group grafted onto the first molecular skeleton. Furthermore, in a case where the functional auxiliary agent includes at least two first coordinating groups, the at least two first coordinating groups may be the same or different. One or more first coordinating groups in the functional auxiliary agent are coordinated with the quantum dot body.

It will be understood that the quantum dot body is the part of the quantum dot material that can emit monochromatic light under stimulation of light or electricity, and has properties of nanoparticles. Here, there is no limitation on the type of quantum dot body.

In some examples, the quantum dot body may include any of II-VI group quantum dots, III-V group quantum dots, IV-VI group quantum dots, core-shell quantum dots and ABX₃ type perovskite quantum dots.

The II-VI group quantum dots may be selected from binary compounds such as one or more of CdS, CdSe, CdTe, ZnS, ZnO, ZnSe, ZnTe, HgSe, HgTe and HgS, ternary compounds such as one or more of HgxCd₁₋ₓTe, HgₓCd₁₋ₓS, HgₓCd₁₋ₓSe, HgₓZn₁₋ₓTe, CdₓZn₁₋ₓSe and CdₓZn₁₋ₓS (0<x<1), but are not limited thereto.

The III-V group quantum dots may be selected from one or a mixture of InP, InAs, InSb, GaAs, GaP, GaN, GaSb, GaNk, InN, AlP, AlN, AlAs, InGaAs and InGaN, but are not limited thereto.

The IV-VI group quantum dots may be selected from one or a mixture of PbS, PbSe and PbTe, but are not limited thereto.

The core-shell quantum dots refer to quantum dots in which one material is the core material and the other material is the shell material. For example, the quantum dots of CdS@ZnS refer that the core material in the quantum dots is CdS and the shell material in the quantum dots is ZnS. The core-shell quantum dots may be selected from one or more of CdS@ZnS, CdSe@CdS, InP@ZnS, CdTe@CdSe, CdSe@ZnTe, CdSe@ZnS, PdS@ZnS, ZnTe@CdSe, ZnSe@CdS and Cd₁₋ₓZnₓS@ZnS (0<x<1), but are not limited thereto.

In the ABX₃ type perovskite quantum dots, A may be one or more of CH₃NH₃⁺(methylamine), NH₂CH═NH₂ (formamidine) and Cs⁺, B may be one or both of Pb²⁺ and Sn²⁺, X may be one or more of C⁻, Br⁻ and I⁻. The ABX₃ type perovskite quantum dots may include CH₃NH₃PbBr₃, CH₃NH₃PbCl₃, CH₃NH₃PbI₃, CsPbBr₃, CsPbCl₃ and CsPbI₃, but are not limited thereto.

In some other examples, the quantum dot body may be other nano-scale materials, such as nanorods and nanosheets. The components of the other nano-scale materials may include at least one of CuInS₂, CuInSe₂, AgInS₂ and the like, but are not limited thereto.

Here, as mentioned above, the solvent may be a single solvent or a mixed solvent, and there is no limitation here. Furthermore, there is no limitation on the type of the single solvent and the type and amount of the mixed solvent, as long as the solvent and the quantum dot material may form the quantum dot solution.

In some examples, the solvent is a mixed solvent, such as a mixed solvent consisting of propylene glycol methyl ether acetate, propylene glycol methyl ether and 3-ethoxyethyl propionate, where the volume fraction of propylene glycol methyl ether acetate is in a range of 55% to 65%, the volume fraction of propylene glycol methyl ether is in a range of 5% to 30%, and the volume fraction of 3-ethoxyethyl propionate is in a range of 5% to 15%.

The first coordinating group is grafted onto the first molecular skeleton, which means that the at least one first coordinating group is connected to a part of the first molecular skeleton by chemical bond. Here, there is no limitation on the type of the first molecular skeleton.

In some examples, the first molecular skeleton may be a straight-chain molecular skeleton such as a carbon chain molecular skeleton, and the carbon chain molecular skeleton may be an alkane molecular skeleton, an alkene molecular skeleton, or an alkyne molecular skeleton.

In some other examples, the first molecular skeleton may be a dendritic molecular skeleton. Here, the dendritic molecular skeleton refers to an organic molecular skeleton having a dendritic structure. The dendritic molecular is synthesized through repeated propagation reactions, and a branching layer is added in each propagation reaction and is referred to as a “generation”. The branching layer includes a main structure (core, branched units, peripheral groups) and a microenvironment (cavity). The core may be a single atom (e.g., nitrogen atom), a dendritic structure (e.g., triphenylamine), a straight-chain structure (e.g., alkane, alkene) or a ring structure (e.g., arene, fluorene, carbazole). The branched unit may be a straight-chain bonding group or a branched bonding group. Here, the branched bonding group has a plurality of branches (i.e., a structure in which branches are connected to a main chain) compared to a straight-chain bonding group. The straight-chain bonding group or the branched bonding group may be an alkane bonding group, an alkene bonding group, an arene bonding group or the like. It can be understood that in a case where the first molecular skeleton is a dendritic molecular skeleton, compared with a straight-chain molecular skeleton, since the dendritic molecular skeleton has a plurality of terminal positions, there may be a relatively large number of first coordinating groups grafted onto the first molecular skeleton.

Here, one or more first coordinating groups of the functional auxiliary agent may be coordinated with a quantum dot body, or may be coordinated with a plurality of quantum dot bodies. That is, there is no limitation on the number of the quantum dot bodies that produce a coordination reaction with the first coordinating group(s) of the functional auxiliary agent.

It can be understood that since there are usually some defects on the surface of the quantum dot body that cannot be passivated, and there may be dangling bonds at the defect positions that are not coordinated by ligands, the quantum dot material is caused to be relatively unstable. In a case where one or more first coordinating groups of the functional auxiliary agent are coordinated with the quantum dot body (bodies), the first coordinating groups and the dangling bonds undergo coordination reaction, so that the defects on the surface of the quantum dot body may be passivated, thereby improving the stability of the quantum dot material.

In some embodiments, a concentration of the quantum dot materials in the quantum dot solution is greater than or equal to 5.0 mg/mL and less than or equal to 50 mg/mL.

For example, the concentration of the quantum dot materials in the quantum dot solution is 5.0 mg/mL, 10.0 mg/mL, 10.8 mg/mL, 12.0 mg/mL, 15.0 mg/mL, 20.0 mg/mL, 25.0 mg/mL, 30.0 mg/mL, 40.0 mg/mL or 50.0 mg/mL.

It can be understood that on one hand, in a case where the concentration of the quantum dot materials in the quantum dot solution is greater than or equal to 5.0 mg/mL, the concentration of the quantum dot materials in the quantum dot solution is relatively high, so that the solid content of the quantum dot material in the quantum dot solution is relatively high, and thus the process controllability may be improved during film formation and drying, and the uniformity of large-area coating and drying may be improved during manufacturing the quantum dot film. On the other hand, in a case where the concentration of the quantum dot materials in the quantum dot solution is greater than a certain value, the solid content of the quantum dot material is relatively high, making it difficult to forming a relatively thin quantum dot film. As a result, through the setting of the concentration of the quantum dot materials in the quantum dot solution being less than or equal to 50.0 mg/mL, a quantum dot film with a suitable film thickness, such as a quantum dot film with a film thickness of 20 nm to 50 nm, may be formed using the quantum dot ink.

In some embodiments, the quantum dot material further includes a ligand material coordinated with the quantum dot body.

It will be understood that the ligand material is an original ligand material, coordinated with the quantum dot body, in the quantum dot material. Here, there is no limitation on the type of the ligand material. In some examples, the ligand material may be selected from any one or a combination of organic acids, organic amines, organic phosphorus and organic thiols. For example, the ligand material is oleic acid, oleylamine or dodecanethiol.

It can be understood that in a case where the quantum dot material further includes a ligand material, when one or more first coordinating groups of the functional auxiliary agent are coordinated with the quantum dot body, there are at least two possible implementations.

In the first implementation, the first coordinating group is directly coordinated with a dangling bond of the quantum dot body that is not coordinated by the ligand material. In this case, at least some of the quantum dot bodies are coordinated with both the ligand material and the functional auxiliary agent.

For example, when the first coordinating group(s) are directly coordinated with

In the second implementation, the functional auxiliary agent undergoes a ligand exchange reaction with the ligand material, that is, the original coordination bond between the ligand material and the quantum dot body is broken, and a new coordination bond is formed between the functional auxiliary agent and the quantum dot material by the first coordinating group. In this case, the functional auxiliary agent may undergo a ligand exchange reaction with some of the ligand materials coordinated with the quantum dot body, or may undergo a ligand exchange reaction with all the ligand materials coordinated with the quantum dot body.

For example, when the functional auxiliary agent and the ligand material undergo a ligand exchange reaction, the ligand exchange reaction may be shown as the

It will be noted that the above two implementations do not exist independently, but may exist simultaneously. For example, as shown in the following formula, in a plurality of functional auxiliary agent molecules, some functional auxiliary agent molecules are coordinated with the dangling bonds of the quantum dot body that are not coordinated by the ligand materials, and some other functional auxiliary agent molecules undergo ligand exchange reaction with the ligand materials. Alternatively, the same functional auxiliary agent molecule contains a plurality of first coordinating groups, some first coordinating groups are coordinated with the dangling bonds of the quantum dot body that are not coordinated by the ligand materials, and some other first coordinating groups undergo ligand exchange reaction with the ligand materials.

Based on the above two possible implementations, in some embodiments, at least some of the quantum dot bodies are coordinated with both the ligand material and the functional auxiliary agent.

It can be understood that in a case where at least some of the quantum dot bodies are coordinated with both the ligand material and the functional auxiliary agent, the stability of the quantum dot material may be improved. Moreover, in this case, due to action of coordination bonds, the functional auxiliary agent may be present in the quantum dot ink throughout a process of forming the quantum dot film by the quantum dot ink. In this way, the viscosity of the quantum dot ink may be maintained within a relatively high range, and the uniformity of large-area coating and drying during manufacturing the quantum dot film may be improved. Moreover, the coffee ring effect appearing during drying may be alleviated. In addition, in this case, the quantum dot film formed by the quantum dot ink may contain the functional auxiliary agent, and the presence of the functional auxiliary agent will not affect the electrical properties of the quantum dot device.

Some embodiments of the ligand exchange reaction between the functional auxiliary agent and the ligand material are exemplarily introduced below.

In some embodiments, in a case where the functional auxiliary agent includes a single first coordinating group, the first coordinating group is a first selected coordinating group. In a case where the functional auxiliary agent includes at least two first coordinating groups, in the at least two first coordinating groups, a first coordinating group having the strongest coordination ability with the quantum dot body is the first selected coordinating group. The ligand material includes a second coordinating group, and the ligand material is coordinated with the quantum dot body through the second coordinating group. The first selected coordinating group is the same as the second coordinating group; alternatively, the first selected coordinating group is different from the second coordinating group, and the coordination ability of the first selected coordinating group with the quantum dot body is stronger than the coordination ability of the second coordinating group with the quantum dot body.

It can be understood that, in a case where the functional auxiliary agent includes a first selected coordinating group, the functional auxiliary agent may undergo a coordination reaction with the quantum dot body at least through the first selected coordinating group. In a case where the first selected coordinating group and the second coordinating group both exist in the quantum dot ink, and the first selected coordinating group is different from the second coordinating group, based on the principle of a higher coordination bonding energy, the quantum dot body is more prone to react with a coordinating group having a stronger coordination ability with the quantum dot body to form a coordination bond. Therefore, in a case where the coordination ability of the first selected coordinating group with the quantum dot body is stronger than the coordination ability of the second coordinating group with the quantum dot body, the quantum dot body is more prone to undergo a coordination reaction with the first selected coordinating group (i.e., the functional auxiliary agent), and thus a ligand exchange reaction may be undergone between the functional auxiliary agent and the ligand material.

In a case where the first selected coordinating group and the second coordinating group both exist in the quantum dot ink, and the first selected coordinating group and the second coordinating group are the same (e.g., both are carboxyl groups), the coordination reaction between the quantum dot body and the functional auxiliary agent and the coordination reaction between the quantum dot body and the ligand material may form a competitive reaction, and usually, a process of the competitive reaction is a dynamic equilibrium process. Thus, a ligand exchange reaction may be undergone between the functional auxiliary agents and at least a part of the ligand materials.

Here, in a case where the functional auxiliary agent includes at least two first coordinating groups, the coordination ability of the first coordinating group other than the first selected coordinating group with the quantum dot body may be stronger than the coordination ability of the second coordinating group with the quantum dot body, or may be weaker than the coordination ability of the second coordinating group with the quantum dot body, which are not limited here.

In some embodiments, the second coordinating group is a sulfhydryl group, and the first selected coordinating group is a sulfhydryl group.

It can be understood that since the first selected coordinating group is the same as the second coordinating group, as described above, the functional auxiliary agent and the ligand material may undergo a ligand exchange reaction.

In some examples, the functional auxiliary agent is 2-methyl-2,4-pentanedithiol, and the first selected coordinating group is a sulfhydryl group; the ligand material is dodecanethiol, and the second coordinating group is a sulfhydryl group. Although the coordination ability of the first selected coordinating group with the quantum dot body is equivalent to the coordination ability of the second coordinating group with the quantum dot body, the functional auxiliary agent 2-methyl-2,4-pentanedithiol has a disulfhydryl structure, and the first molecular skeleton of the functional auxiliary agent 2-methyl-2,4-pentanedithiol has a shorter chain segment than a second molecular skeleton of the ligand material dodecanethiol, so that the probability of a coordination reaction undergone between the quantum dot body and the functional auxiliary agent 2-methyl-2,4-pentanedithiol may increase. Therefore, the functional auxiliary agent 2-methyl-2,4-pentanedithiol may be coordinated with the quantum dot body through a ligand exchange reaction and/or a direct coordination reaction to generate a quantum dot material with a dual ligand structure. In the obtained quantum dot film, a proportion of the number of dodecanethiol ligands to the total number of ligands is in a range of 5% to 95%, inclusive, and a proportion of the number of 2-methyl-2,4-pentanedithiol ligands to the total number of ligands is in a range of 5% to 95%, inclusive. Here, the total number of ligands refers to a sum of the number of dodecanethiol ligands and the number of 2-methyl-2,4-pentanedithiol ligands.

In some embodiments, the second coordinating group is a carboxyl group, and the first selected coordinating group is any of a carboxyl group and a sulfhydryl group.

It can be understood that the coordination ability of the sulfhydryl group with the quantum dot body is stronger than the coordination ability of the carboxyl group with the quantum dot body. In a case where the second coordinating group is a carboxyl group and the first selected coordinating group is any of a carboxyl group and a sulfhydryl group, the first selected coordinating group is the same as the second coordinating group, or the coordination ability of the first selected coordinating group with the quantum dot body is stronger than the coordination ability of the second coordinating group with the quantum dot body. In this way, as described above, the functional auxiliary agent and the ligand material may undergo a ligand exchange reaction.

In some embodiments, the second coordinating group is a sulfonic acid group, and the first selected coordinating group is any of a sulfhydryl group, a carboxyl group and a sulfonic acid group.

It can be understood that the coordination ability of each of the sulfhydryl group and the carboxyl group with the quantum dot body is stronger than the coordination ability of the sulfonic acid group and the quantum dot body. In a case where the second coordinating group is a sulfonic acid group, and the first selected coordinating group is any of a sulfhydryl group, a carboxyl group and a sulfonic acid group, the first selected coordinating group is the same as the second coordinating group, or the coordination ability of the first selected coordinating group with the quantum dot body is stronger than the coordination ability of the second coordinating group with the quantum dot body. In this way, as described above, the functional auxiliary agent and the ligand material may undergo a ligand exchange reaction.

In some embodiments, the second coordinating group is a phosphate group, and the first selected coordinating group is any of a sulfhydryl group, a carboxyl group, a sulfonic acid group and a phosphate group.

It can be understood that the coordination ability of each of the sulfhydryl group, the carboxyl group and the sulfonic acid group with the quantum dot body is stronger than the coordination ability of the phosphate group with the quantum dot body. In a case where the second coordinating group is a phosphate group, and the first selected coordinating group is any of a sulfhydryl group, a carboxyl group, a sulfonic acid group and a phosphate group, the first selected coordinating group is the same as the second coordinating group, or the coordination ability of the first selected coordinating group with the quantum dot body is stronger than the coordination ability of the second coordinating group with the quantum dot body. In this way, as described above, the functional auxiliary agent and the ligand material may undergo a ligand exchange reaction.

In some embodiments, the second coordinating group is an amine group, and the first selected coordinating group is any of a sulfhydryl group, a carboxyl group, a sulfonic acid group, a phosphate group and an amine group.

It can be understood that the coordination ability of each of the sulfhydryl group, the carboxyl group, the sulfonic acid group and the phosphate group with the quantum dot body is stronger than the coordination ability of the amine group with the quantum dot body. In a case where the second coordinating group is an amine group, and the first selected coordinating group is any of a sulfhydryl group, a carboxyl group, a sulfonic acid group, a phosphate group and an amine group, the first selected coordinating group is the same as the second coordinating group, or the coordination ability of the first selected coordinating group with the quantum dot body is stronger than the coordination ability of the second coordinating group with the quantum dot body. In this way, as described above, the functional auxiliary agent and the ligand material may undergo a ligand exchange reaction.

In some embodiments, the second coordinating group is a phospholipid group, and the first selected coordinating group is any of a sulfhydryl group, a carboxyl group, a sulfonic acid group, a phosphate group, an amine group and a phospholipid group.

It can be understood that the coordination ability of each of the sulfhydryl group, the carboxyl group, the sulfonic acid group, the phosphate group and the amine group with the quantum dot body is stronger than the coordination ability of the phospholipid group with the quantum dot body. In a case where the second coordinating group is a phospholipid group, and the first selected coordinating group is any of a sulfhydryl group, a carboxyl group, a sulfonic acid group, a phosphate group, an amine group and a phospholipid group, the first selected coordinating group is the same as the second coordinating group, or the coordination ability of the first selected coordinating group with the quantum dot body is stronger than the coordination ability of the second coordinating group with the quantum dot body. In this way, as described above, the functional auxiliary agent and the ligand material may undergo a ligand exchange reaction.

In some embodiments, in a case where the functional auxiliary agent includes a single first coordinating group, the first coordinating group is the first selected coordinating group. In a case where the functional auxiliary agent includes at least two first coordinating groups, in the at least two first coordinating groups, a first coordinating group having the strongest coordination ability with the quantum dot body is the first selected coordinating group. The ligand material includes a second coordinating group, and the ligand material is coordinated with the quantum dot body through the second coordinating group. The coordination ability of the second coordinating group with the quantum dot body is stronger than the coordination ability of the first selected coordinating group with the quantum dot body. The volume percentage of the functional auxiliary agent in the quantum dot ink is greater than or equal to 5%.

For example, the volume percentage of the functional auxiliary agent in the quantum dot ink is 5.0%, 10.0%, 16.0%, 21.0%, 25.0%, 31.0%, 36.0%, 40.0%, 46.0% or 50%.

It can be understood that in a case where the functional auxiliary agent includes the first selected coordinating group, the functional auxiliary agent may undergo a coordination reaction with the quantum dot body at least through the first selected coordinating group. Since the coordination ability of the second coordinating group with the quantum dot body is stronger than the coordination ability of the first selected coordinating group with the quantum dot body, the possibility that the quantum dot body and the second coordinating group undergo a coordination reaction is relatively large. In this case, since the combination of the ligand (e.g., a ligand material or a functional auxiliary agent) and the quantum dot body is a dynamic equilibrium process, in a case where the concentration of the functional auxiliary agent around the quantum dot body is relatively high, the functional auxiliary agent may be coordinated with the quantum dot body. Therefore, by setting the volume percentage of the functional auxiliary agent in the quantum dot ink to be greater than or equal to 5%, the concentration of the first selected coordinating group in the quantum dot ink may increase, so that the probability of the coordination reaction undergone between the quantum dot body and the functional auxiliary agent may increase. In this way, a ligand exchange reaction may be undergone between the functional auxiliary agent and the ligand material.

In some embodiments, in a case where the functional auxiliary agent includes a single first coordinating group, the first coordinating group is the first selected coordinating group. In a case where the functional auxiliary agent includes at least two first coordinating groups, in the at least two first coordinating groups, a first coordinating group having the strongest coordination ability with the quantum dot body is the first selected coordinating group. The ligand material includes a second molecular skeleton and a second coordinating group grafted onto the second molecular skeleton, and the ligand material is coordinated with the quantum dot body through the second coordinating group. The coordination ability of the second coordinating group with the quantum dot body is stronger than the coordination ability of the first selected coordinating group with the quantum dot body. The steric hindrance of the second molecular skeleton is greater than the steric hindrance of the first molecular skeleton.

Here, the steric hindrance, also known as spatial hindrance, refers to the mutual repulsion caused by groups within the molecule in spatial arrangement. The steric hindrance effect may cause changes in the molecular configuration, symmetry, reactivity, and the like. Accordingly, the steric effect is an effect that the molecular reactivity is affected since atoms or groups close to a reaction center in the molecule occupy a certain spatial position.

It can be understood that in a case where the functional auxiliary agent includes the first selected coordinating group, the functional auxiliary agent may undergo a coordination reaction with the quantum dot body at least through the first selected coordinating group. Since the second coordinating group has a stronger coordination ability with the quantum dot body than the first selected coordinating group, the possibility that the quantum dot body and the second coordinating group undergo a coordination reaction is relatively large. In this case, by reducing the steric hindrance of the first molecular skeleton, the functional auxiliary agent may be prone to be closer to the quantum dot body in the quantum dot ink than the ligand material. In this way, the probability of the coordination reaction undergone between the quantum dot body and the functional auxiliary agent may increase, and a ligand exchange reaction may be undergone between the functional auxiliary agent and the ligand material.

In some embodiments, the first selected coordinating group is a carboxyl group and the second coordinating group is a sulfhydryl group.

It can be understood that the coordination ability of the sulfhydryl group with the quantum dot body is stronger than the coordination ability of the carboxyl group with the quantum dot body. In a case where the first coordinating group is a carboxyl group and the second coordinating group is a sulfhydryl group, the volume percentage of the functional auxiliary agent in the quantum dot ink may be set greater than or equal to 5%, and/or the steric hindrance of the second molecular skeleton may be set greater than the steric hindrance of the first molecular skeleton. By increasing the concentration of the first selected coordinating group in the quantum dot ink and/or reducing the steric hindrance of the first molecular skeleton, the functional auxiliary agent and the ligand material may undergo a ligand exchange reaction.

In some embodiments, the first selected coordinating group is a sulfonic acid group, and the second coordinating group is any of a sulfhydryl group and a carboxyl group.

It can be understood that the coordination ability of each of the sulfhydryl group and the carboxyl group with the quantum dot body is stronger than the coordination ability of the sulfonic acid group with the quantum dot body. In a case where the first selected coordinating group is a sulfonic acid group and the second coordinating group is any of a sulfhydryl group and a carboxyl group, the volume percentage of the functional auxiliary agent in the quantum dot ink may be set greater than or equal to 5%, and/or the steric hindrance of the second molecular skeleton may be set greater than the steric hindrance of the first molecular skeleton, so that the functional auxiliary agent and the ligand material may undergo a ligand exchange reaction.

In some embodiments, the first selected coordinating group is a phosphate group, and the second coordinating group is any of a sulfhydryl group, a carboxyl group and a sulfonic acid group.

It can be understood that the coordination ability of each of the sulfhydryl group, the carboxyl group and the sulfonic acid group with the quantum dot body is stronger than the coordination ability of the phosphate group with the quantum dot body. In a case where the first selected coordinating group is a phosphate group, and the second coordinating group is any of a sulfhydryl group, a carboxyl group and a sulfonic acid group, the volume percentage of the functional auxiliary agent in the quantum dot ink may be set greater than or equal to 5%, and/or the steric hindrance of the second molecular skeleton may be set greater than the steric hindrance of the first molecular skeleton, so that the functional auxiliary agent and the ligand material may undergo a ligand exchange reaction.

In some embodiments, the first selected coordinating group is an amine group, and the second coordinating group is any of a sulfhydryl group, a carboxyl group, a sulfonic acid group and a phosphate group.

It can be understood that the coordination ability of each of the sulfhydryl group, the carboxyl group, the sulfonic acid group and the phosphate group with the quantum dot body is stronger than the coordination ability of the amine group with the quantum dot body. In a case where the first selected coordinating group is an amine group, and the second coordinating group is any of a sulfhydryl group, a carboxyl group, a sulfonic acid group and a phosphate group, the volume percentage of the functional auxiliary agent in the quantum dot ink may be set greater than or equal to 5%, and/or the steric hindrance of the second molecular skeleton may be set greater than the steric hindrance of the first molecular skeleton, so that the functional auxiliary agent and the ligand material may undergo a ligand exchange reaction.

In some examples, the functional auxiliary agent is N,N-dimethylethylenediamine, and the first selected coordinating group is an amine group; the ligand material is oleic acid, and the second coordinating group is a carboxyl group. The volume percentage of the functional auxiliary agent in the quantum dot ink is 10%. In this way, since the volume percentage of the functional auxiliary agent in the quantum dot ink is relatively high, and a first molecular skeleton of the functional auxiliary agent N,N-dimethylethylenediamine has a shorter chain segment than a second molecular skeleton of the ligand material oleic acid, so that the probability of a coordination reaction undergone between the quantum dot body and the functional auxiliary agent N,N-dimethylethylenediamine may increase. Therefore, the functional auxiliary agent may be coordinated with the quantum dot body through a ligand exchange reaction and/or a direct coordination reaction to generate a quantum dot material with a dual ligand structure. In the obtained quantum dot film, a proportion of the number of oleic acid ligands to the total number of ligands is in a range of 50% to 90%, inclusive, and a proportion of the number of N,N-dimethylethylenediamine ligands to the total number of ligands is in a range of 10% to 50%, inclusive. Here, the total number of ligands refers to a sum of the number of oleic acid ligands and the number of N,N-dimethylethylenediamine ligands.

In some embodiments, the first selected coordinating group is a phospholipid group, and the second coordinating group is any of a sulfhydryl group, a carboxyl group, a sulfonic acid group, a phosphate group and an amine group.

It can be understood that the coordination ability of each of the sulfhydryl group, the carboxyl group, the sulfonic acid group, the phosphate group and the amine group with the quantum dot body is stronger than the coordination ability of the phospholipid group with the quantum dot body. In a case where the first selected coordinating group is a phospholipid group, and the second coordinating group is any of a sulfhydryl group, a carboxyl group, a sulfonic acid group, a phosphate group and an amine group, the volume percentage of the functional auxiliary agent in the quantum dot ink may be set greater than or equal to 5%, and/or the steric hindrance of the second molecular skeleton may be set greater than the steric hindrance of the first molecular skeleton, so that the functional auxiliary agent and the ligand material may undergo a ligand exchange reaction.

In some embodiments, the number of carbon atoms in the first molecular skeleton is greater than or equal to 4 and less than or equal to 8.

For example, the number of the carbon atoms in the first molecular skeleton is 4, 5, 6, 7 or 8.

It can be understood that on one hand, in a case where the number of the carbon atoms in the first molecular skeleton is greater than or equal to 4 and less than or equal to 8, the steric hindrance of the first molecular skeleton may be relatively small, so that the functional auxiliary agent is prone to approach the quantum dot body, and thus the functional auxiliary agent may be more prone to undergo a ligand exchange reaction with the ligand material. On the other hand, it will be understood that in a case of a relatively long chain segment of the ligand coordinated with the quantum dot body, due to the steric hindrance effect, charge transfer between the quantum dot bodies is hindered to a certain extent. Therefore, in a case where the number of the carbon atoms in the first molecular skeleton is greater than or equal to 4 and less than or equal to 8, the chain segment of the first molecular skeleton is relatively short. In this way, after the functional auxiliary agent and the ligand material undergo a ligand exchange reaction, the chain segment of the ligand coordinated with the quantum dot body may be made shorter. Therefore, the charge transfer between the quantum dot bodies may be easy, which is beneficial to charge transfer, and the conductive properties of the quantum dot film formed by the quantum dot ink may be improved.

In some embodiments, the quantum dot solution includes a quantum dot material and a solvent. The boiling point of the functional auxiliary agent is greater than the boiling point of the solvent.

In some examples, the boiling point of the quantum dot solution is greater than the boiling point of the solvent, and the boiling point of the functional auxiliary agent is greater than the boiling point of the quantum dot solution.

It can be understood that in a case where the boiling point of the functional auxiliary agent is greater than the boiling point of the solvent, the quantum dot ink including the functional auxiliary agent has relatively low volatility compared with a quantum dot ink not including the functional auxiliary agent. In this way, the volatilization of the quantum dot ink may be reduced to reduce migration of the quantum dot solution, so as to alleviate the coffee ring effect appearing during drying.

It will be noted that in a case where the boiling point of the functional auxiliary agent in the quantum dot ink is greater than the boiling point of the solvent, the functional auxiliary agent may include a first coordinating group coordinated with the quantum dot body, or may not include a first coordinating group coordinated with the quantum dot body, which is not limited here.

In some examples, the boiling point of the functional auxiliary agent in the quantum dot ink is greater than the boiling point of the solvent, the functional auxiliary agent includes a first molecular skeleton and at least one first coordinating group grafted onto the first molecular skeleton, and one or more first coordinating groups of the functional auxiliary agent are coordinated with the quantum dot body. In this case, the functional auxiliary agent may not only improve the uniformity of large-area coating and drying and reduce the fluidity of the quantum dot solution, but also passivate the defects on the surface of the quantum dot body, so that the stability of the quantum dot material may be improved. Moreover, the migration of the quantum dot solution may be reduced, thereby alleviating the coffee ring effect appearing during drying.

In some embodiments, the first coordinating group includes a sulfhydryl group and/or a carboxyl group, and the volume percentage of the functional auxiliary agent in the quantum dot ink is in a range of 0.1% to 50%, inclusive.

In some examples, the first coordinating group includes a sulfhydryl group, and the volume percentage of the functional auxiliary agent in the quantum dot ink may be 0.1%, 0.5%, 1.0%, 10.0%, 20.0%, 30.1%, 40.0% or 50.0%.

In this case, for example, the functional auxiliary agent may be selected from any one or a combination of heptyl mercaptan, octyl mercaptan, isooctyl mercaptan, 2-sulfhydryl-2,4-pentanediol, 2-methyl-2,4-pentanedithiol, 1,5-pentanedithiol and polythiol oligomer.

In some other examples, the first coordinating group includes a carboxyl group, and the volume percentage of the functional auxiliary agent in the quantum dot ink may be 0.1%, 0.7%, 2.0%, 10.5%, 20.0%, 30.0%, 42.0% or 50.0%.

In this case, for example, the functional auxiliary agent may be 5-aminovaleric acid.

In some other examples, the functional auxiliary agent includes at least two first coordinating groups, and the first coordinating groups are a sulfhydryl group and a carboxyl group. The volume percentage of the functional auxiliary agent in the quantum dot ink may be 0.1%, 0.4%, 3.0%, 10.5%, 20.6%, 30.0%, 40.0% or 50.0%.

In this case, for example, the functional auxiliary agent may be selected from any one or a combination of 3-mercaptobutyric acid and 5-mercaptopentanoic acid.

It can be understood that in a case where the functional auxiliary agent contains a sulfhydryl group and/or a carboxyl group (e.g., selected from any one or a combination of the above materials), the functional auxiliary agent may increase the viscosity of the quantum dot ink to be greater than or equal to 2.0 mPa·s, so as to improve the uniformity of large-area coating and drying and reduce the fluidity of the quantum dot solution. Moreover, in a case where the functional auxiliary agent includes a first coordinating group coordinated with the quantum dot body, the functional auxiliary agent may passivate the defects on the surface of the quantum dot body, thereby improving the stability of the quantum dot material. In a case where the boiling point of the functional auxiliary agent is greater than the boiling point of the solvent, the functional auxiliary agent may reduce the migration of the quantum dot solution and alleviate the coffee ring effect appearing during drying.

In some embodiments, the first coordinating group includes an amino group and/or an amine group, and the volume percentage of the functional auxiliary agent in the quantum dot ink is in a range of 0.1% to 30%, inclusive.

In some examples, the first coordinating group includes an amino group, and the volume percentage of the functional auxiliary agent in the quantum dot ink may be 0.1%, 0.4%, 1.0%, 10.0%, 15.0%, 20.5%, 25.0% or 30.0%.

In some other examples, the first coordinating group includes an amine group, and the volume percentage of the functional auxiliary agent in the quantum dot ink may be 0.1%, 0.5%, 3.0%, 10.0%, 16.0%, 20.5%, 24.0% or 30.0%.

In this case, for example, the functional auxiliary agent may be selected from any one or a combination of ethanolamine, dimethylethanolamine, N,N-dimethylethylenediamine, 1,2-diaminopropane, 2-methylbutylenediamine, 2-methylpentanediamine and 5-aminovaleric acid.

It can be understood that in a case where the functional auxiliary agent contains an amino group and/or an amine group (e.g., selected from any one or a combination of the above materials), the functional auxiliary agent may increase the viscosity of the quantum dot ink to be greater than or equal to 2.0 mPa·s, so as to improve the uniformity of large-area coating and drying and reduce the fluidity of the quantum dot solution. Moreover, in a case where the functional auxiliary agent includes a first coordinating group coordinated with the quantum dot body, the functional auxiliary agent may passivate the defects on the surface of the quantum dot body, thereby improving the stability of the quantum dot material. In a case where the boiling point of the functional auxiliary agent is greater than the boiling point of the solvent, the functional auxiliary agent may reduce the migration of the quantum dot solution and alleviate the coffee ring effect appearing during drying.

In some embodiments, the first coordinating groups include phosphate groups and/or phospholipid groups, and the volume percentage of the functional auxiliary agent in the quantum dot ink is in a range of 0.1% to 30%, inclusive.

In some examples, the first coordinating group includes a phosphate group, and the volume percentage of the functional auxiliary agent in the quantum dot ink may be 0.1%, 0.5%, 1.5%, 12.0%, 16.0%, 20.5%, 27.0% or 30.0%.

In some examples, the first coordinating group includes a phospholipid group, and the volume percentage of the functional auxiliary agent in the quantum dot ink may be 0.1%, 0.6%, 1.5%, 11.0%, 16.0%, 20.5%, 25.0% or 30.0%.

In this case, for example, the functional auxiliary agent may be any one or a combination of fatty alcohol ether phosphate and fatty alcohol polyoxyethylene ether phosphate.

In some examples, the first coordinating groups include a phosphate group and a phospholipid group, and the volume percentage of the functional auxiliary agent in the quantum dot ink may be 0.1%, 0.4%, 1.5%, 10.0%, 15.0%, 20.5%, 25.0% or 30.0%.

It can be understood that in a case where the functional auxiliary agent contains a phosphate group and/or a phospholipid group (e.g., selected from any one or a combination of the above materials), the functional auxiliary agent may increase the viscosity of the quantum dot ink to be greater than or equal to 2.0 mPa·s, so as to improve the uniformity of large-area coating and drying and reduce the fluidity of the quantum dot solution. Moreover, in a case where the functional auxiliary agent includes a first coordinating group coordinated with the quantum dot body, the functional auxiliary agent may passivate the defects on the surface of the quantum dot body, thereby improving the stability of the quantum dot material. In a case where the boiling point of the functional auxiliary agent is greater than the boiling point of the solvent, the functional auxiliary agent may reduce the migration of the quantum dot solution and alleviate the coffee ring effect appearing during drying.

In some embodiments, the first coordinating group includes a sulfonic acid group, and the volume percentage of the functional auxiliary agent in the quantum dot ink is in a range of 0.1% to 30%, inclusive.

For example, in a case where the first coordinating group includes a sulfonic acid group, the volume percentage of the functional auxiliary agent in the quantum dot ink is 0.1%, 0.8%, 3.0%, 10.0%, 15.5%, 20.0%, 26.0% or 30.0%.

In this case, for example, the functional auxiliary agent may be selected from any one or a combination of octane sulfonic acid, decylsulfonic acid, dodecyl sulfonic acid, tetradecyl sulfonic acid, 1-hexadecanesulfonic acid, octadecyl sulfonic acid, 4-decylbenzenesulfonic acid, dodecylbenzenesulfonic acid, tetradecylbenzenesulfonic acid, hexadecylbenzenesulfonic acid and octadecylbenzenesulfonic acid.

It can be understood that in a case where the functional auxiliary agent contains a sulfonic acid group (e.g., any one or a combination of the above materials), the functional auxiliary agent may increase the viscosity of the quantum dot ink to be greater than or equal to 2.0 mPa·s, so as to improve the uniformity of large-area coating and drying and reduce the fluidity of the quantum dot solution. Moreover, in a case where the functional auxiliary agent includes a first coordinating group coordinated with the quantum dot body, the functional auxiliary agent may passivate the defects on the surface of the quantum dot body, thereby improving the stability of the quantum dot material. In a case where the boiling point of the functional auxiliary agent is greater than the boiling point of the solvent, the functional auxiliary agent may reduce the migration of the quantum dot solution and alleviate the coffee ring effect appearing during drying.

Some embodiments of the present disclosure further provide a quantum dot film. The quantum dot film is made of the quantum dot ink as described in any of the above embodiments.

In some examples, a method for forming the quantum dot film by the quantum dot ink includes steps S1 to S2.

In S1, a quantum dot ink is applied to a preset position on a surface of a substrate, where the quantum dot ink includes a quantum dot solution and a functional auxiliary agent miscible with the quantum dot solution; a volume percentage of the functional auxiliary agent in the quantum dot ink is in a range of 0.1% to 50%, inclusive; and the functional auxiliary agent is configured to make the viscosity of the quantum dot ink greater than or equal to 2.0 mPa·s.

For example, the coating process of the quantum dot ink is a slit coating process, a spin coating process, a blade coating process or an inkjet printing process.

For example, the preset position on the surface of the substrate is within an opening Q of a barrier layer N as described in detail below.

In S2, the quantum dot ink is dried by heating, or cured by light irradiation to form a quantum dot film.

Beneficial effects that can be achieved by the quantum dot film provided in some embodiments of the present disclosure are the same as the beneficial effects that can be achieved by the quantum dot ink provided in the above technical solutions, and details are not repeated again.

In some embodiments, a material of the quantum dot film includes a functional auxiliary agent.

Here, the material of the quantum dot film includes a functional auxiliary agent. In this case, the functional auxiliary agent may be coordinated with the quantum dot body or may not be coordinated with the quantum dot body, which is not limited here.

In some examples, the functional auxiliary agent is coordinated with the quantum dot body through the first coordinating group. In this case, the functional auxiliary agent in the quantum dot film may passivate the defects on the surface of the quantum dot body, thereby improving the stability of the quantum dot material.

It can be understood that the presence of the functional auxiliary agent will not affect the electrical properties of the quantum dot device. Moreover, in a case where the material of the quantum dot film includes the functional auxiliary agent, the functional auxiliary agent may be present in the quantum dot ink throughout the process. In this way, the viscosity of the quantum dot ink may be maintained within a relatively high range, and the uniformity of large-area coating and drying during manufacturing the quantum dot film may be improved; moreover, the coffee ring effect appearing during drying may be alleviated.

In addition, in a case where the quantum dot ink is formed into a quantum dot film by heating and drying, the boiling point of the functional auxiliary agent included in the quantum dot film is usually relatively high and higher than that of the solvent. In this way, during heating, the functional auxiliary agent may reduce volatilization of the quantum dot ink, thereby alleviating the coffee ring effect appearing during drying.

Some embodiments of the present disclosure further provide a display panel. As shown in FIGS. 1 and 2, the display panel 1000 includes a plurality of quantum dot films M as described in any of the above embodiments and a barrier layer N. The barrier layer N includes a plurality of openings Q, and the plurality of quantum dot films M are located in the plurality of openings Q.

Here, as shown in FIG. 1, the plurality of quantum dot films M may be located in the plurality of openings Q in one-to-one correspondence; alternatively, as shown in FIG. 2, the plurality of quantum dot films M may be located in some openings Q of the plurality of openings Q.

In some examples, as shown in FIG. 1, the display panel 1000 further includes a light-emitting substrate 100, and the light-emitting substrate 100 includes quantum dot films M and a barrier layer N. In some other examples, as shown in FIG. 2, the display panel 1000 further includes a color conversion substrate 200, and the color conversion substrate 200 includes quantum dot films M and a barrier layer N. The case where the light-emitting substrate 100 includes the quantum dot films M and the barrier layer N will be described exemplarily below.

In some examples, as shown in FIG. 1, the quantum dot film M may be a light-emitting layer 11 and is applied to the light-emitting substrate 100. The light-emitting substrate 100 includes a plurality of light-emitting devices 10 that are regularly arranged (e.g., arranged in an array). In this case, the light-emitting devices 10 are quantum dot light-emitting diodes (QLED) light-emitting devices 10.

For example, as shown in FIG. 1, the light-emitting substrate 100 further includes a base 20 and a pixel defining layer 30 disposed on the base 20. It will be understood that the pixel defining layer 30 is the above barrier layer N. The pixel defining layer 30 has a plurality of openings Q, and the plurality of light-emitting devices 10 may be disposed in one-to-one correspondence with the plurality of openings Q. In this way, the plurality of quantum dot films M may be disposed in the plurality of openings Q in one-to-one correspondence.

In some examples, the plurality of light-emitting devices 10 emit light of the same type, such as blue light. In this case, the quantum dot body of the quantum dot film 11 is blue quantum dots. In this case, the color conversion substrate 200 may be used to convert part of light emitted by the light-emitting substrate 100 into light of other colors (e.g., red light or green light), so as to achieve full-color display of the display panel 1000.

In some other examples, as shown in FIG. 1, the plurality of light-emitting devices 10 emit light of a plurality of colors. In this case, the plurality of light-emitting devices 10 may include a red light-emitting device 10R, a green light-emitting device 10G and a blue light-emitting device 10B arranged in a first direction X. The quantum dot body of the quantum dot film of the red light-emitting device 10R is red quantum dots; the quantum dot body of the quantum dot film of the green light-emitting device 10G is green quantum dots; and the quantum dot body of the quantum dot film of the blue light-emitting device 10B is blue quantum dots.

For example, as shown in FIG. 1, each light-emitting device 10 in the plurality of light-emitting devices 10 further includes an anode 12 and a cathode 13, and the quantum dot film 11 is disposed between the anode 12 and the cathode 13. In this case, the light-emitting principle of the QLED light-emitting device 10 may be as that through circuits connected to the anode 12 and the cathode 13, holes are injected into the quantum dot film 11 using the anode 12, and electrons are injected into the quantum dot film 11 using the cathode 13; the electrons and the holes form excitons in the quantum dot film 11, and the excitons are transitioned to a ground state through radiation to emit photons.

For example, as shown in FIG. 1, the light-emitting device 10 may further include an electron transport functional layer 15 located between the quantum dot film 11 and the cathode 13, and a hole transport functional layer 14 located between the quantum dot film 11 and the anode 12. The electron transport functional layer includes at least one of an electron injection layer, an electron transport layer 151 and a hole barrier layer; and the hole transport functional layer includes at least one of a hole injection layer 141, a hole transport layer 142 and an electron barrier layer.

For example, as shown in FIG. 1, the anodes 12 of the plurality of light-emitting devices 10 may be separately provided, and the cathode 13 of the plurality of light-emitting devices 10 may be shared. Alternatively, the cathodes 13 of the plurality of light-emitting devices 10 may be separately provided, and the anode 12 of the plurality of light-emitting devices 10 may be shared. In this way, due to action of different driving currents, the plurality of light-emitting devices 10 may emit light independently as needed, thereby realizing full-color display of the display panel 1000.

The case where the light-emitting substrate 100 includes the quantum dot films M and the barrier layer N is introduced exemplarily, and the case where the color conversion substrate 200 includes the quantum dot films M and the barrier layer N will be described exemplarily below.

In some examples, the quantum dot film M may be a color conversion portion 210 and is applied to the color conversion substrate 200. The color conversion substrate 200 includes a plurality of color conversion portions 210.

For example, as shown in FIG. 2, the color conversion substrate 200 further includes a substrate 220 and a barrier pattern 230 disposed on the substrate 220. It will be understood that the barrier pattern 230 is the above barrier layer N. The barrier pattern 230 has a plurality of openings Q, and the plurality of color conversion portions 210 may be disposed in some of the openings Q, such as an opening for emitting red light and an opening for emitting green light.

In some examples, as shown in FIG. 2, the plurality of color conversion portions 210 convert and generate lights of a plurality of color. In this case, the display panel 1000 may further include a light-emitting substrate 100 for emitting blue light. The light-emitting substrate 100 is, for example, an organic light-emitting diode (OLED) light-emitting substrate. In this case, the plurality of color conversion portions 210 may include a red color conversion portion 210R and a green color conversion portion 210G arranged in a second direction Y. The quantum dot body of the red color conversion portion 210R is red quantum dots, and the red color conversion portion 210R is configured to convert blue light into red light. The quantum dot body of the green color conversion portion 210G is green quantum dots, and the green color conversion portion 210G is configured to convert blue light into green light. In this case, the display panel 1000 is a QD-OLED display panel, which may take into account advantages of high brightness, high color volume and high efficiency of quantum dots, and combine advantages of true black state, high contrast, wide viewing angle and wide color gamut of OLED devices, so as to achieve high-quality display effects and have advantages of wide color gamut, high color conversion efficiency (CCE) and wide viewing angle.

In some embodiments, as shown in FIG. 2, the display pane 1000 further includes a filling layer 300 located between the light-emitting substrate 100 and the color conversion substrate 200. In this way, the filling layer 300 may be used to fill a cell-opposite gap between the color conversion substrate 200 and the light-emitting substrate 100, so that the light-emitting substrate 100 and the color conversion substrate 200 are bonded together.

In some examples, as shown in FIG. 2, the color conversion substrate 200 further includes a light-transmitting portion 211. The light-transmitting portion 211, the red color conversion portion 210R and the green color conversion portion 210G are arranged in the second direction Y.

In some embodiments, as shown in FIG. 2, the color conversion substrate 200 may further include a light barrier layer 240 located between the barrier pattern 230 and the substrate 220. The light barrier layer 240 may include a light absorption pattern 241 and a plurality of color filter portions 242. The light absorption pattern 241 includes a plurality of openings D directly opposite to the plurality of openings Q. The plurality of color filter portions 242 are disposed in the plurality of openings D in one-to-one correspondence. The plurality of color filter portions 242 include a red color filter portion 243 directly opposite to the red color conversion portion 210R, a green color filter portion 244 directly opposite to the green color conversion portion 210G and a blue color filter portion 245 directly opposite to the light-transmitting portion 211. The color filter portion 242 may be configured to allow light of the same color as itself to pass through and filter out light of a different color as itself, so that the color gamut of the display panel 1000 may be rather high.

Based on the above embodiments, the display panel 1000 may be an OLED panel, an OLED television, a QLED panel, a QLED television, a micro LED panel, a micro LED television, a mini LED panel, a mini LED television, a monitor, a mobile phone, a navigator, or any other product or component with display function. The display panel 1000 may be any display panel that displays images whether in motion (such as a video) or fixed (such as a still image), and regardless of text or image. More specifically, it is expected that the display panel 1000 in the embodiments may be implemented in or associated with a variety of electronic devices. The variety of electronic devices may include (but are not limit to), for example, mobile telephones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

Beneficial effects that can be achieved by the display panel provided in some embodiments of the present disclosure are the same as the beneficial effects that can be achieved by the quantum dot film provided in the above technical solutions, and details are not repeated again.

In order to objectively evaluate technical effects of the embodiments of the present disclosure, the technical solutions provided in the present disclosure will be described exemplary in detail through the following experimental examples and comparative examples. Depending on differences in functional auxiliary agents, quantum dot solutions and measurement data, the following experimental examples and comparative examples are divided into a first group of test examples, a second group of test examples, a third group of test examples, a fourth group of test examples and a fifth group of test examples.

### (First Group of Test Examples)

In this group of test examples, different quantum dot inks are used to form quantum dot films by blade coating and drying, and morphology and ligand ratios of the formed quantum dot films are measured.

Experimental Example 1 and Comparative Example 1 use the same blade coating and drying processes. The specific blade coating process is as follows: forming a thin film by coating using a blade coating device, setting a blade coating speed to 10 mm/s during coating and setting a distance between the blade and a substrate to 20 μm. The specific drying process is as follows: using a vacuum decompression equipment to perform drying.

The quantum dot ink in Comparative Example 1 is composed of a quantum dot solution. The quantum dot body is CdSe quantum dots, the ligand material is oleic acid, the solvent is propylene glycol methyl ether acetate, and the concentration of the quantum dot materials is 12 mg/mL.

The quantum dot ink in Experimental Example 1 is composed of a quantum dot solution and a functional auxiliary agent. The quantum dot ink in Experimental Example 1 is prepared by the following method: mixing the quantum dot ink (i.e., the quantum dot solution) in Comparative Example 1 and the functional auxiliary agent N,N-dimethylethylenediamine in a volume ratio of 90:10, and performing thorough stir to achieve uniform mixture, thereby obtaining the quantum dot ink in Experimental Example 1.

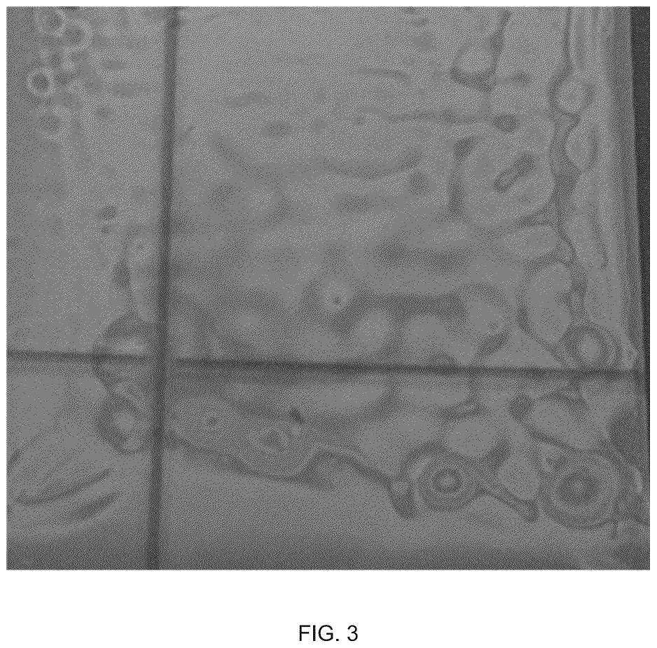

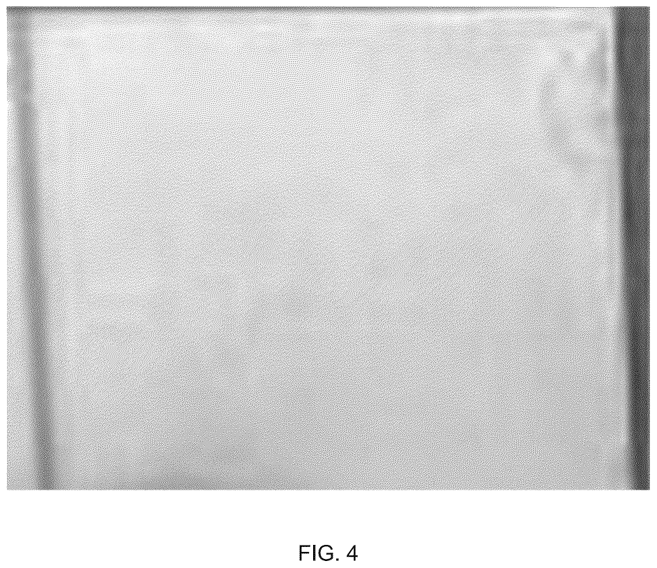

Based on the quantum dot inks in Comparative Example 1 and Experimental Example 1, quantum dot films are formed by blade coating and drying as above. The morphology of the quantum dot film formed in Comparative Example 1 is shown in FIG. 3, and the morphology of the quantum dot film formed in Experimental Example 1 is shown in FIG. 4.

It can be seen from FIGS. 3 and 4 that circular and other irregular shaped patterns appear locally in the quantum dot film formed in Comparative Example 1, an obvious coffee ring effect appears, and an uneven phenomenon is presented. In contrast, the quantum dot film formed in Experimental Example 1 has a significant improvement in morphology compared with Comparative Example 1, the coffee ring effect is suppressed, and the uniformity of the quantum dot film is relatively good. This is because the quantum dot solution in Comparative Example 1 has a relatively fast evaporation rate, and a coffee ring effect is obvious, resulting in poor uniformity of the formed quantum dot film. In Experimental Example 1, the functional auxiliary agent N,N-dimethylethylenediamine is added to the quantum dot ink, so that the viscosity of the quantum dot ink may increase, and the uniformity of large-area coating and drying during manufacturing the quantum dot film may be improved. Moreover, the fluidity of the quantum dot solution may be reduced, and the volatility of the quantum dot ink may be reduced, thereby alleviating the coffee ring effect appearing during drying.

In addition, in Experimental Example 1, the ligand material oleic acid has a relatively long chain segment. Due to the steric hindrance effect of the long-chain coordination, there are some defects, that cannot be passivated, on the surface of the quantum dot body CdSe. In this case, the addition of the functional auxiliary agent N,N-dimethylethylenediamine may passivate the dangling bonds, that are not coordinated by the coordination material, on the surface of the quantum dot body CdSe and reduce the defects on the surface. The functional auxiliary agent N,N-dimethylethylenediamine includes an amine group as a first coordinating group. Compared with the first coordinating group amine group of the functional auxiliary agent N,N-dimethylethylenediamine, the second coordinating group carboxyl group of the ligand material oleic acid has a relatively high coordination bonding energy, and thus has a relatively strong coordination ability with the quantum dot body CdSe. However, the volume percentage of the functional auxiliary agent in the quantum dot ink in Experimental Example 1 is 10%, so that the quantum dot body CdSe is surrounded by a large number of functional auxiliary agent molecules, and thus the probability of the coordination reaction undergone between the quantum dot body CdSe and the functional auxiliary agent N,N-dimethylethylenediamine may increase. In addition, compared with the second molecular skeleton of the ligand material oleic acid, the first molecular skeleton of the functional auxiliary agent N,N-dimethylethylenediamine has a shorter chain segment, and is more prone to approach the quantum dot body CdSe, so that the probability of the coordination reaction undergone between the quantum dot body CdSe and the functional auxiliary agent N,N-dimethylethylenediamine may also increase. Therefore, during stirring and mixing the quantum dot solution and the functional auxiliary agent, the functional auxiliary agent N,N-dimethylethylenediamine may be coordinated with the quantum dot body CdSe through a ligand exchange reaction, so as to replace some of the long-chain oleic acid ligands with short-chain N,N-dimethylethylenediamine ligands, and the reaction process is shown in the following formula (I); and/or the functional auxiliary agent N,N-dimethylethylenediamine may passivate the dangling bonds, that are not coordinated by oleic acid, on the surface of the quantum dot body CdSe through a direct coordination reaction, and the reaction process is shown in the following formula (II). In this way, after drying to remove excess solvent, the quantum dot material with a dual ligand structure may be generated. Through a plurality of tests and measurements, a proportion of the number of oleic acid ligands in the quantum dot film to the total number of ligands is in a range of 50% and 90%, inclusive, and a proportion of the number of N,N-dimethylethylenediamine ligands in the quantum dot film to the total number of ligands is in a range of 10% and 50%, inclusive. Here, the total number of ligands refers to a sum of the number of oleic acid ligands and the number of N,N-dimethylethylenediamine ligands.

### (Second Group of Test Examples)

In this group of test examples, different quantum dot inks are used to form quantum dot films by blade coating and drying, and morphology and ligand ratios of the formed quantum dot films are measured.

Experimental Example 2 and Comparative Example 2 use the same blade coating and drying processes. The specific blade coating process is as follows: forming a thin film by coating using a blade coating device, setting a blade coating speed to 10 mm/s during coating and setting a distance between the blade and a substrate to 15 μm. The specific drying process is as follows: using a vacuum decompression equipment to perform drying.

The quantum dot ink in Comparative Example 2 is composed of a quantum dot solution. The quantum dot body is CdSe quantum dots, the ligand material is dodecanethiol, and the solvent is a mixed solvent composed of propylene glycol methyl ether and 3-ethoxyethyl propionate, where the volume fraction of propylene glycol methyl ether is in a range of 65% to 75%, and the volume fraction of 3-ethoxyethyl propionate is in a range of 25% to 35%. The concentration of the quantum dot materials is 20 mg/mL.

The quantum dot ink in Experimental Example 2 is composed of a quantum dot solution and a functional auxiliary agent. The quantum dot ink in Experimental Example 2 is prepared by the following method: mixing the quantum dot ink (i.e., the quantum dot solution) in Comparative Example 2 and the functional auxiliary agent 2-methyl-2,4-pentanedithiol in a volume ratio of 50:50, and performing thorough stir to achieve uniform mixture, thereby obtaining the quantum dot ink in Experimental Example 2. The concentration of the quantum dot materials in the quantum dot ink is 10 mg/mL.

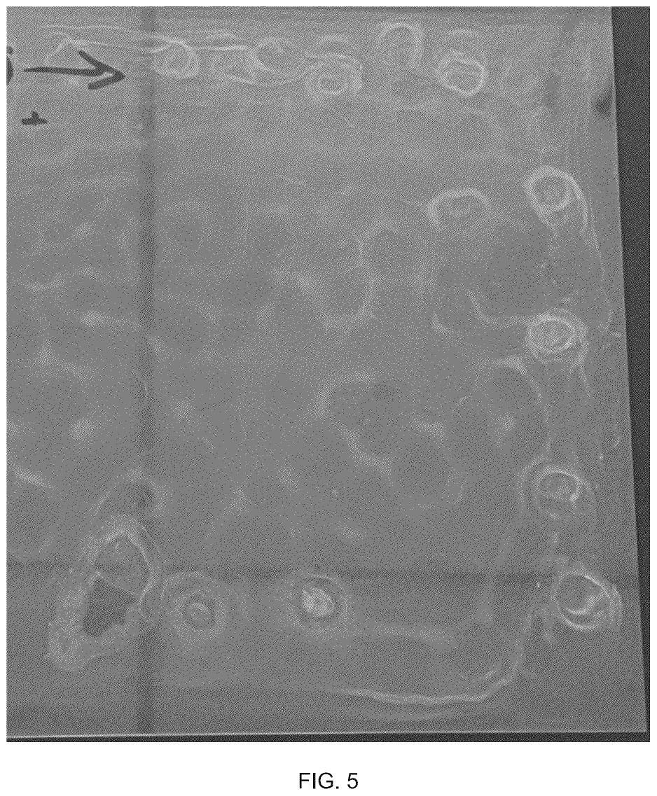

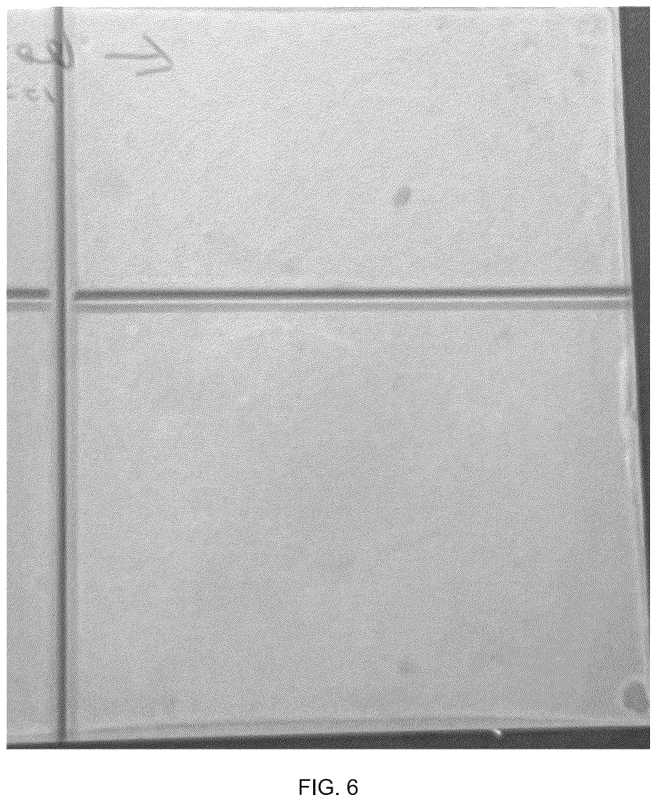

Based on the quantum dot inks in Comparative Example 2 and Experimental Example 2, quantum dot films are formed by blade coating and drying as above. The morphology of the quantum dot film formed in Comparative Example 2 is shown in FIG. 5, and the morphology of the quantum dot film formed in Experimental Example 2 is shown in FIG. 6.

It can be seen from FIGS. 5 and 6 that more circular patterns appear at an edge of the quantum dot film formed in Comparative Example 2, an edge part of the circular pattern is relatively thick and the middle part of the circular pattern is relatively thin; circular patterns of different sizes also appear at the middle of the quantum dot film; an coffee ring effect is obvious on the whole, and an uneven phenomenon is presented. In contrast, the quantum dot film formed in Experimental Example 2 has a significant improvement in morphology compared with Comparative Example 2, the coffee ring effect is suppressed, and the uniformity of the quantum dot film is relatively good. This is because the quantum dot solution in Comparative Example 2 has relatively low viscosity, and a coffee ring effect is obvious, resulting in poor uniformity of the formed quantum dot film. In Experimental Example 2, the functional auxiliary agent 2-methyl-2,4-pentanedithiol is added to the quantum dot ink, so that the viscosity of the quantum dot ink may increase, and the uniformity of large-area coating and drying during manufacturing the quantum dot film may be improved. Moreover, the fluidity of the quantum dot solution may be reduced, and the volatility of the quantum dot ink may be reduced, thereby alleviating the coffee ring effect appearing during drying.

In addition, in Experimental Example 2, the functional auxiliary agent 2-methyl-2,4-pentanedithiol includes a sulfhydryl group as a first coordinating group, and the ligand material dodecanethiol includes a sulfhydryl group as a second coordinating group. The coordination ability of the first coordinating group with the quantum dot body CdSe is equivalent to the coordination ability of the second coordinating group with the quantum dot body CdSe. However, the functional auxiliary agent 2-methyl-2,4-pentanedithiol in the quantum dot ink in Experimental Example 2 has a dual sulfhydryl structure, and compared with the second molecular skeleton of the ligand material dodecanethiol, the first molecular skeleton of the functional auxiliary agent 2-methyl-2,4-pentanedithiol has a shorter chain segment, and is more prone to approach the quantum dot body CdSe, so that the probability of the coordination reaction undergone between the quantum dot body CdSe and the functional auxiliary agent 2-methyl-2,4-pentanedithiol may increase. Therefore, after adding a large amount of functional auxiliary agents to the quantum dot solution, the functional auxiliary agent 2-methyl-2,4-pentanedithiol may be coordinated with the quantum dot body CdSe through a ligand exchange reaction, so as to replace some of the long-chain dodecanethiol ligands with short-chain 2-methyl-2,4-pentanedithiol ligands, and the reaction process is shown in the following formula (III); and/or the functional auxiliary agent 2-methyl-2,4-pentanedithiol may passivate original defects on the surface of the quantum dot body CdSe through a direct coordination reaction, and the reaction process is shown in the following formula (IV). In this way, after drying, the quantum dot material with a dual ligand structure may be generated. Through a plurality of tests and measurements, a proportion of the number of dodecanethiol ligands in the quantum dot film to the total number of ligands is in a range of 5% and 95%, inclusive, and a proportion of the number of 2-methyl-2,4-pentanedithiol ligands in the quantum dot film to the total number of ligands is in a range of 5% and 95%, inclusive. Here, the total number of ligands refers to a sum of the number of dodecanethiol ligands and the number of 2-methyl-2,4-pentanedithiol ligands.

### (Third Group of Test Examples)

In this group of test examples, different quantum dot inks are used to form quantum dot films by blade coating and drying, and morphology of the formed quantum dot films are measured.

Experimental Example 3 and Comparative Example 3 use the same blade coating and drying processes. The specific blade coating process is as follows: forming a thin film by coating using a blade coating device, setting a blade coating speed to 15 mm/s during coating and setting a distance between the blade and a substrate to 20 μm. The specific drying process is as follows: using a vacuum decompression equipment to perform drying.

The quantum dot ink in Comparative Example 3 is composed of a quantum dot solution. The quantum dot body is ZnO quantum dots, the solvent is ethanol, and the concentration of the quantum dot body is 20 mg/mL.

The quantum dot ink in Experimental Example 3 is composed of a quantum dot solution and a functional auxiliary agent. The quantum dot ink in Experimental Example 3 is prepared by the following method: mixing the quantum dot ink (i.e., the quantum dot solution) in Comparative Example 3 and the functional auxiliary agent ethanolamine in a volume ratio of 90:10, and performing thorough stir to achieve uniform mixture, thereby obtaining the quantum dot ink in Experimental Example 3. The viscosity of the quantum dot ink is 2.5 mPa·s.

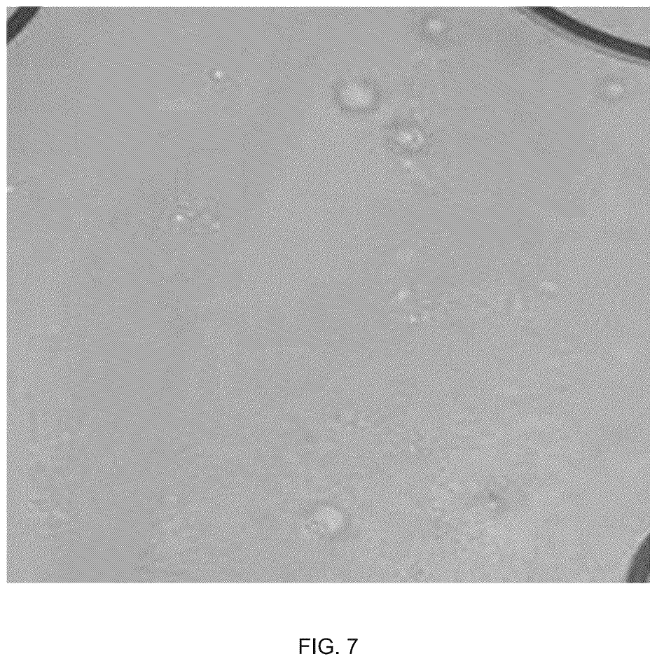

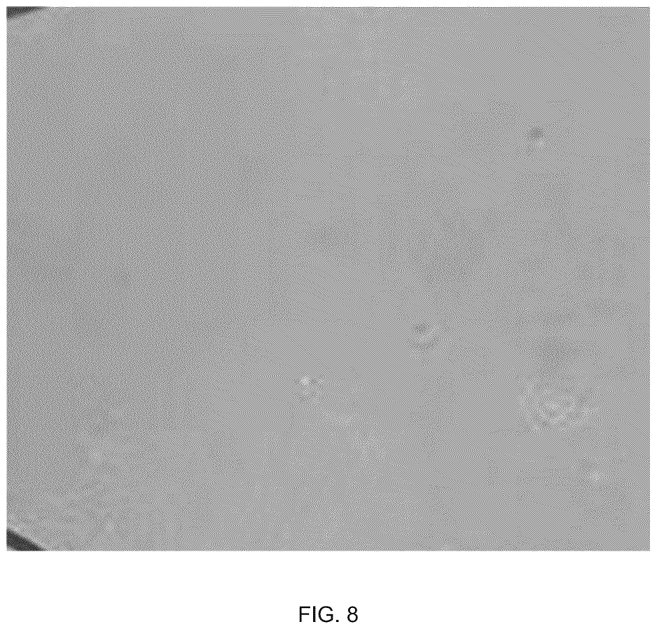

Based on the quantum dot inks in Comparative Example 3 and Experimental Example 3, quantum dot films are formed by blade coating and drying as above. The morphology of the quantum dot film formed in Comparative Example 3 is shown in FIG. 7, and the morphology of the quantum dot film formed in Experimental Example 3 is shown in FIG. 8.

It can be seen from FIGS. 7 and 8 that circular patterns appear locally in the quantum dot film formed in Comparative Example 3, different positions of the quantum dot film have uneven thicknesses and have a relatively large difference, and an uneven phenomenon is presented on the whole. In contrast, the quantum dot film formed in Experimental Example 3 has a significant improvement in film formation uniformity. This is because the boiling point of the solvent ethanol in Comparative Example 3 is 78 °C, the boiling point is relatively low and the volatility is relatively high, resulting in poor uniformity of the formed quantum dot film. In Experimental Example 3, the functional auxiliary agent ethanolamine is added to the quantum dot ink. The boiling point of the functional auxiliary agent ethanolamine is 170 °C, and the viscosity of the functional auxiliary agent ethanolamine at 25 °C is 18.95 mPa·s. Therefore, the viscosity of the quantum dot ink may increase, and the volatility of the quantum dot ink may be reduced, so that the migration of the quantum dots ZnO caused by the evaporation of the solvent may be reduced, thereby improving the film formation uniformity of the quantum dot film.

### (Fourth Group of Test Examples)

In this group of test examples, different quantum dot inks are used to form quantum dot films by blade coating and drying, and morphology of the formed quantum dot films are measured.

Experimental Example 4 and Comparative Example 4 use the same blade coating and drying processes. The specific blade coating process is as follows: forming a thin film by coating using a blade coating device, setting a blade coating speed to 10 mm/s during coating and setting a distance between the blade and a substrate to 20 μm. The specific drying process is as follows: using a vacuum decompression equipment to perform drying.

The quantum dot ink in Comparative Example 4 is composed of a quantum dot solution. The quantum dot body is InP quantum dots, the second coordinating group of the ligand material is an amine group, the solvent is a mixed solvent consisting of propylene glycol methyl ether acetate, propylene glycol methyl ether and 3-ethoxyethyl propionate, where the volume fraction of propylene glycol methyl ether acetate is 65%, and the viscosity is 1.1 mPa-s; the volume fraction of propylene glycol methyl ether is 30%, and the viscosity is 1.75 mPa-s; the volume fraction of 3-ethoxyethyl propionate is 5%, and the viscosity is 1.0 mPa-s. The concentration of the quantum dot materials is 15 mg/mL, and the viscosity is 1.4 mPa-s.

The quantum dot ink in Experimental Example 4 is composed of a quantum dot solution and a functional auxiliary agent. The quantum dot ink in Experimental Example 4 is prepared by the following method: mixing the quantum dot ink (i.e., the quantum dot solution) in Comparative Example 4 and the functional auxiliary agent 5-mercaptopentanoic acid in a volume ratio of 80:20, and performing thorough stir to achieve uniform mixture, thereby obtaining the quantum dot ink in Experimental Example 4. The viscosity of the quantum dot ink is 3.2 mPa·s. The boiling point of 5-mercaptopentanoic acid is 265 °C.

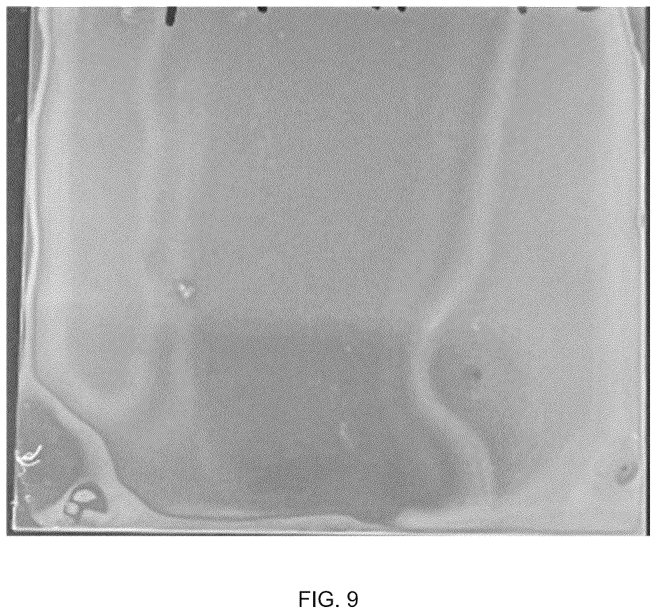

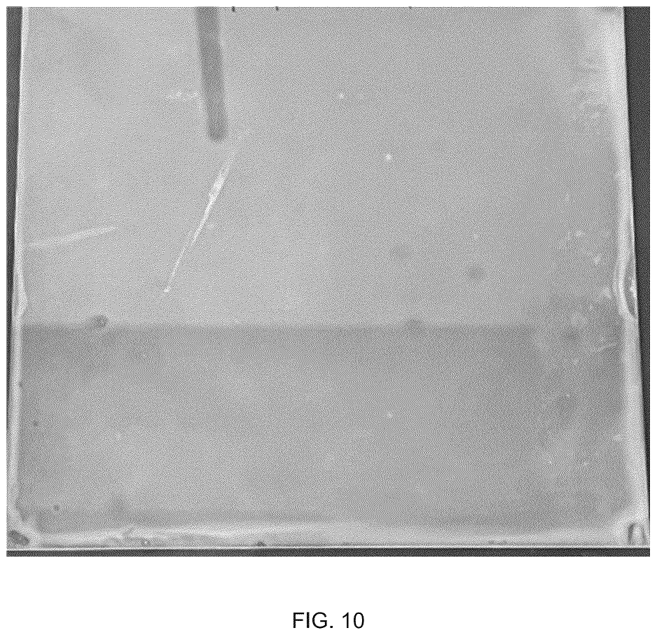

Based on the quantum dot inks in Comparative Example 4 and Experimental Example 4, quantum dot films are formed by blade coating and drying as above. The morphology of the quantum dot film formed in Comparative Example 4 is shown in FIG. 9, and the morphology of the quantum dot film formed in Experimental Example 4 is shown in FIG. 10.

It can be seen from FIGS. 9 and 10 that compared with Comparative Example 4, the film formation uniformity of the quantum dot film formed in Experimental Example 4 is improved. This is because in Experimental Example 4, the functional auxiliary agent 5-mercaptopentanoic acid is added to the quantum dot ink, so that the viscosity and the volatility of the quantum dot ink may be adjusted. As a result, the viscosity and the boiling point of the quantum dot ink may increase, the fluidity of the quantum dot solution may be reduced, and the volatility of the quantum dot ink may be reduced, thereby improving the uniformity of large-area coating and drying during manufacturing the quantum dot film.

In addition, in Experimental Example 4, the functional auxiliary agent 5-mercaptopentanoic acid includes a sulfhydryl group and a carboxyl group as first coordinating groups, both of which have strong coordination bonding energy. Compared with the first coordinating groups sulfhydryl group and carboxyl group, the second coordinating group amine group has a weaker coordination bonding energy. In this way, after adding the functional auxiliary agent to the quantum dot solution, the functional auxiliary agent 5-mercaptopentanoic acid may be coordinated with the quantum dot body InP through a ligand exchange reaction, so that the ligand amine group on the surface of the quantum dot body InP is replaced with the ligand 5-mercaptopentanoic acid, thereby improving the stability of the quantum dot film.

### (Fifth Group of Test Examples)

In this group of test examples, different quantum dot inks are used to form quantum dot films by coating and drying; green quantum dot light-emitting devices are manufactured using the formed quantum dot films, and the current densities, brightness, and current efficiencies of the manufactured green quantum dot light-emitting devices are measured.

The quantum dot ink for forming the quantum dot film in Experimental Example 5 is composed of a quantum dot solution and a functional auxiliary agent. The quantum dot body is CdSe quantum dots, the ligand material is oleic acid, the solvent is octane, and the concentration of the quantum dot materials in the quantum dot solution is 15 mg/mL. During manufacturing, the quantum dot solution and the functional auxiliary agent 2-methyl-2,4-pentanedithiol are mixed in a volume ratio of 60:40, and stirred thoroughly to achieve uniform mixture, thereby obtaining the quantum dot ink in Experimental Example 5. Then, the quantum dot film is formed by blade coating and drying. The specific blade coating process is as follows: forming a thin film by coating using a blade coating device, setting a blade coating speed to 10 mm/s during coating and setting a distance between the blade and a substrate to 15 μm. The specific drying process is as follows: using a vacuum decompression equipment to perform drying.

The structure of the green quantum dot light-emitting device is shown as the structure 10G in FIG. 1. Therefore, before the quantum dot film is formed, the manufacturing of a hole injection layer and a hole transport layer is further included. After the quantum dot film is formed, an electron transport layer is further included. The hole injection layer, the hole transport layer and the electron transport layer are formed by blade coating and drying. The materials for forming the hole injection layer, the hole transport layer and the electron transport layer are PEDOT:PSS, TFB and ZnO respectively.

In addition to differences in the quantum dot ink and the process for forming the quantum dot film, the manufacturing method of the green quantum dot light-emitting device in Comparative Example 5 is the same as the manufacturing method of the green quantum dot light-emitting device in Experimental Example 5. The quantum dot ink in Comparative Example 5 does not include the functional auxiliary agent 2-methyl-2,4-pentanedithiol, and is composed of the above quantum dot solution. The quantum dot film in Comparative Example 5 is formed by spin coating.

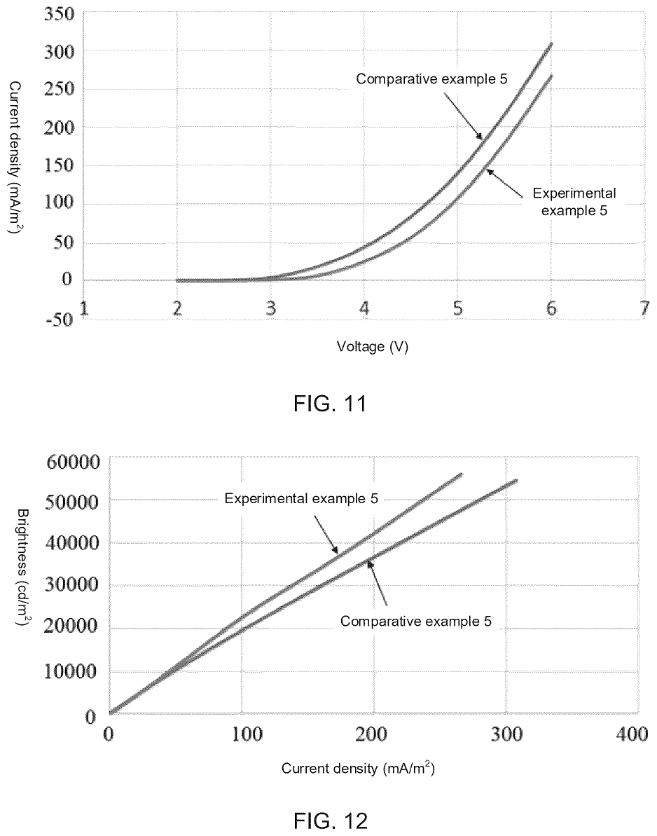

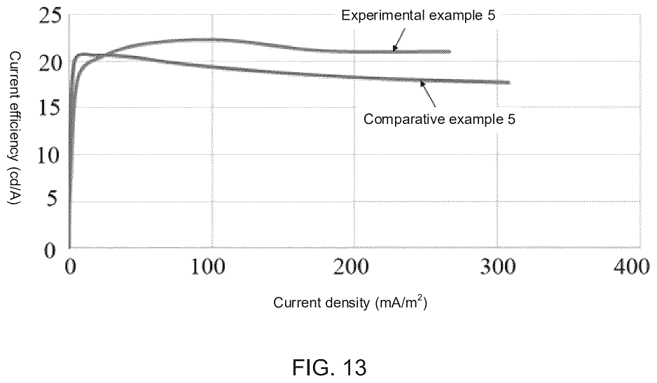

Based on the green quantum dot light-emitting devices in Comparative Example 5 and Experimental Example 5, voltages, brightness and efficiencies of the manufactured green quantum dot light-emitting devices are measured. The curve of current density changing with voltage is shown in FIG. 11, the curve of brightness changing with current density is shown in FIG. 12, and the curve of current efficiency changing with current density is shown in FIG. 13.

It can be seen from FIGS. 11 to 13 that compared with Comparative Example 5, the green quantum dot light-emitting device in Experimental Example 5 has a smaller current density and has a higher brightness at the same current density. Moreover, the maximum current efficiency of the green quantum dot light-emitting device in Comparative Example 5 is 20.58 cd/A, and the maximum current efficiency of the green quantum dot light-emitting device in Experimental Example 5 is 22.22 cd/A. The maximum current efficiency in Experimental Example 5 is slightly high. It can be seen that adding the functional auxiliary agent to the quantum dot ink not only does not affect the electrical properties of the green quantum dot light-emitting device, but also improves the electrical properties of the quantum dot light-emitting device.

In Experimental Example 5, compared with the ligand material oleic acid, the functional auxiliary agent 2-methyl-2,4-pentanedithiol has a smaller steric hindrance, and compared with the second coordinating group carboxyl group, the first coordinating group sulfhydryl group has a larger coordination bonding energy. As a result, the coordination bonding energy of the functional auxiliary agent 2-methyl-2,4-pentanedithiol is greater than the coordination bonding energy of the ligand material oleic acid. Therefore, in a process of stirring and mixing the quantum dot solution and the functional auxiliary agent, the functional auxiliary agent 2-methyl-2,4-pentanedithiol may be coordinated with the quantum dot body CdSe at least through a ligand exchange reaction, so as to replace some of the long-chain oleic acid ligands with short-chain 2-methyl-2,4-pentanedithiol ligands, and the reaction process is shown in the following formula (V). In this way, the conductive properties of the quantum dot film may be improved.

It can be seen from the above experimental examples and comparative examples that in the present disclosure, through the provision of the quantum dot ink including a quantum dot solution and a functional auxiliary agent miscible with the quantum dot solution, the uniformity of large-area coating and drying during manufacturing the quantum dot film may be improved, the fluidity of the quantum dot solution may be reduced, and the coffee ring effect appearing during drying may be alleviated. In addition, the conductive properties of the quantum dot film formed by the quantum dot ink may also be improved.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A quantum dot ink, comprising a quantum dot solution and a functional auxiliary agent miscible with the quantum dot solution; wherein a volume percentage of the functional auxiliary agent in the quantum dot ink is in a range of 0.1% to 50%, inclusive; and the functional auxiliary agent is configured to make a viscosity of the quantum dot ink greater than or equal to 2.0 mPa·s.

2. The quantum dot ink according to claim 1, wherein the quantum dot solution includes quantum dot materials and a solvent; a quantum dot material includes a quantum dot body; the functional auxiliary agent includes a first molecular skeleton and at least one first coordinating group grafted onto the first molecular skeleton; wherein
one or more first coordinating groups of the functional auxiliary agent are coordinated with the quantum dot body.

3. The quantum dot ink according to claim 2, wherein the quantum dot material further includes a ligand material coordinated with the quantum dot body; and at least part of quantum dot bodies are each coordinated with both a ligand material and a functional auxiliary agent.

4. The quantum dot ink according to claim 3, wherein in a case where the functional auxiliary agent includes a first coordinating group, the first coordinating group is a first selected coordinating group; in a case where the functional auxiliary agent includes at least two first coordinating groups, in the at least two first coordinating groups, a first coordinating group having strongest coordination ability with the quantum dot body is the first selected coordinating group; and
the ligand material includes a second coordinating group, and the ligand material is coordinated with the quantum dot body through the second coordinating group; wherein
the first selected coordinating group is same as the second coordinating group; or
the first selected coordinating group is different from the second coordinating group, and a coordination ability of the first selected coordinating group with the quantum dot body is stronger than a coordination ability of the second coordinating group with the quantum dot body.

5. The quantum dot ink according to claim 4, wherein the second coordinating group is a sulfhydryl group, and the first selected coordinating group is a sulfhydryl group; or
the second coordinating group is a carboxyl group, and the first selected coordinating group is any of a carboxyl group and a sulfhydryl group; or
the second coordinating group is a sulfonic acid group, and the first selected coordinating group is any of a sulfhydryl group, a carboxyl group and a sulfonic acid group; or
the second coordinating group is a phosphate group, and the first selected coordinating group is any of a sulfhydryl group, a carboxyl group, a sulfonic acid group and a phosphate group; or
the second coordinating group is an amine group, and the first selected coordinating group is any of a sulfhydryl group, a carboxyl group, a sulfonic acid group, a phosphate group and an amine group; or
the second coordinating group is a phospholipid group, and the first selected coordinating group is any of a sulfhydryl group, a carboxyl group, a sulfonic acid group, a phosphate group, an amine group and a phospholipid group.

6. The quantum dot ink according to claim 3, wherein in a case where the functional auxiliary agent includes a first coordinating group, the first coordinating group is a first selected coordinating group; in a case where the functional auxiliary agent includes at least two first coordinating groups, in the at least two first coordinating groups, a first coordinating group having strongest coordination ability with the quantum dot body is the first selected coordinating group; and
the ligand material includes a second coordinating group, and the ligand material is coordinated with the quantum dot body through the second coordinating group; a coordination ability of the second coordinating group with the quantum dot body is stronger than a coordination ability of the first selected coordinating group with the quantum dot body; and a volume percentage of the functional auxiliary agent in the quantum dot ink is greater than or equal to 5%.

7. The quantum dot ink according to claim 3, wherein in a case where the functional auxiliary agent includes a first coordinating group, the first coordinating group is a first selected coordinating group; in a case where the functional auxiliary agent includes at least two first coordinating groups, in the at least two first coordinating groups, a first coordinating group having strongest coordination ability with the quantum dot body is the first selected coordinating group;
the ligand material includes a second molecular skeleton and a second coordinating group grafted onto the second molecular skeleton, and the ligand material is coordinated with the quantum dot body through the second coordinating group; and
a coordination ability of the second coordinating group with the quantum dot body is stronger than a coordination ability of the first selected coordinating group with the quantum dot body; and a steric hindrance of the second molecular skeleton is greater than a steric hindrance of the first molecular skeleton.

8. The quantum dot ink according to claim 6, wherein the first selected coordinating group is a carboxyl group, and the second coordinating group is a sulfhydryl group; or
the first selected coordinating group is a sulfonic acid group, and the second coordinating group is any of a sulfhydryl group and a carboxyl group; or
the first selected coordinating group is a phosphate group, and the second coordinating group is any of a sulfhydryl group, a carboxyl group and a sulfonic acid group; or
the first selected coordinating group is an amine group, and the second coordinating group is any of a sulfhydryl group, a carboxyl group, a sulfonic acid group and a phosphate group; or
the first selected coordinating group is a phospholipid group, and the second coordinating group is any of a sulfhydryl group, a carboxyl group, a sulfonic acid group, a phosphate group and an amine group.

9. The quantum dot ink according to claim 2, wherein a number of carbon atoms in the first molecular skeleton is greater than or equal to 4 and less than or equal to 8; or
a concentration of the quantum dot materials in the quantum dot solution is greater than or equal to 5.0 mg/mL and less than or equal to 50 mg/mL.

10. The quantum dot ink according to to claim 1, wherein the quantum dot solution includes quantum dot materials and a solvent; and a boiling point of the functional auxiliary agent is greater than a boiling point of the solvent; or
a viscosity of the functional auxiliary agent is greater than or equal to 5.0 mPa·s.

11. (canceled)

12. The quantum dot ink according to claim 1, wherein the first coordinating group includes a sulfhydryl group and/or a carboxyl group; and the volume percentage of the functional auxiliary agent in the quantum dot ink is in the range of 0.1% to 50%, inclusive.

13. The quantum dot ink according to claim 12, wherein the functional auxiliary agent is selected from any one or a combination of 3-mercaptobutyric acid, 5-mercaptopentanoic acid, heptyl mercaptan, octyl mercaptan, isooctyl mercaptan, 2-sulfhydryl-2,4-pentanediol, 2-methyl-2,4-pentanedithiol, 1,5-pentanedithiol, polythiol oligomer and 5-aminovaleric acid.

14. The quantum dot ink according to claim 1, wherein the first coordinating group includes an amino group and/or an amine group; and the volume percentage of the functional auxiliary agent in the quantum dot ink is in a range of 0.1% to 30%, inclusive.

15. The quantum dot ink according to claim 14, wherein the functional auxiliary agent is selected from any one or a combination of ethanolamine, dimethylethanolamine, N,N-dimethylethylenediamine, 1,2-diaminopropane, 2-methylbutylenediamine, 2-methylpentanediamine and 5-aminovaleric acid.

16. The quantum dot ink according to claim 1, wherein the first coordinating group includes a phosphate group and/or a phospholipid group; and the volume percentage of the functional auxiliary agent in the quantum dot ink is in a range of 0.1% to 30%, inclusive.

17. The quantum dot ink according to claim 16, wherein the functional auxiliary agent is selected from any one or a combination of fatty alcohol ether phosphate and fatty alcohol polyoxyethylene ether phosphate.

18. The quantum dot ink according to claim 1, wherein the first coordinating group includes a sulfonic acid group; and the volume percentage of the functional auxiliary agent in the quantum dot ink is in a range of 0.1% to 30%, inclusive.

19. The quantum dot ink according to claim 18, wherein the functional auxiliary agent is selected from any one or a combination of octane sulfonic acid, decylsulfonic acid, dodecyl sulfonic acid, tetradecyl sulfonic acid, 1-hexadecanesulfonic acid, octadecyl sulfonic acid, 4-decylbenzenesulfonic acid, dodecylbenzenesulfonic acid, tetradecylbenzenesulfonic acid, hexadecylbenzenesulfonic acid and octadecylbenzenesulfonic acid.

20. (canceled)

21. A quantum dot film, the quantum dot film being made of the quantum dot ink according to claim 1.

22. (canceled)

23. A display panel, comprising a plurality of quantum dot films each according to claim 21; and
a barrier layer, wherein the barrier layer includes a plurality of openings, and the plurality of quantum dot films are located in the plurality of openings.
